(19) United States
(12) Patent Application Publication
(10) Pub. No.: US 2023/0103145 A1
(43) Pub. Date: Mar. 30, 2023

(54) APPARATUS FOR FABRICATING DISPLAY PANEL AND FABRICATING METHOD THEREOF

(71) Applicant: Samsung Display Co., LTD., (US)

(72) Inventors: Jin Woo CHOI, Seoul (KR); Sung Kook PARK, Suwon-si (KR); Sung Eun BAEK, Suwon-si (KR); Soo Chul KIM, Hwaseong-si (KR)

(21) Appl. No.: 17/752,599

(22) Filed: May 24, 2022

(30) Foreign Application Priority Data
Sep. 27, 2021 (KR) 10-2021-0127018

(51) Int. Cl. H01L 33/00; H01L 27/15

(52) U.S. Cl. CPC H01L 33/005; H01L 27/156

(57) ABSTRACT

An apparatus for fabricating a display panel includes a fixing frame configured to secure an outer periphery of a first transfer film on which light emitting elements are arranged, a film mounting member on which the fixing frame is mounted, a stretching processing member configured to stretch the first transfer film by pressing a rear surface of the first transfer film in a forward direction, and a transfer processing member configured to transfer the light emitting elements to a support film or a second transfer film, the light emitting elements having an interval therebetween changed due to stretching of the first transfer film.

### CROSS-REFERENCE TO RELATED APPLICATION

This application claims priority to, and the benefit of, Korean Patent Application No. 10-2021-0127018 filed on Sep. 27, 2021 in the Korean Intellectual Property Office, the contents of which in its entirety are herein incorporated by reference.

### BACKGROUND

### 1. Field

The present disclosure relates to an apparatus for fabricating a display panel and a fabricating method thereof.

### 2. Description of the Related Art

The importance of display devices has steadily increased with the development of multimedia technology. In response thereto, various types of display devices, such as an organic light emitting display (OLED), a liquid crystal display (LCD), and the like have been used.

A display device is a device for displaying an image, and includes a display panel, such as a light emitting display panel or a liquid crystal display panel. Among them, the light emitting display panel may include a light emitting diode (LED), and the light emitting diode may include an organic light emitting diode using an organic material as a fluorescent material, or an inorganic light emitting diode using an inorganic material as a fluorescent material.

When fabricating a display panel using an inorganic light emitting diode as a light emitting element, fabricating apparatuses for precisely locating micro LEDs on a substrate of the display panel should be developed.

### SUMMARY

Aspects of the present disclosure provide an apparatus for fabricating a display panel capable of facilitating fabricating and arrangement of light emitting diodes, and reducing a fabricating cost, and a fabricating method thereof.

Aspects of the present disclosure also provide an apparatus for fabricating a display panel capable of precisely and accurately locating the light emitting diodes on a substrate of the display panel by reducing or minimizing a defect rate when locating the light emitting diodes, and a fabricating method thereof.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to one or more embodiments of the disclosure, an apparatus for fabricating a display panel, the apparatus including a fixing frame configured to secure an outer periphery of a first transfer film on which light emitting elements are arranged, a film mounting member on which the fixing frame is mounted, a stretching processing member configured to stretch the first transfer film by pressing a rear surface of the first transfer film in a forward direction, and a transfer processing member configured to transfer the light emitting elements to a support film or a second transfer film, the light emitting elements having an interval therebetween changed due to stretching of the first transfer film.

The fixing frame may include first and second assembly frames having a circular or polygonal opening, and having a circular or polygonal panel or frame structure in which the opening is formed.

The first and second assembly frames may be configured to overlap each other with the first transfer film therebetween, and are configured to press and secure partial areas of front and rear surfaces and an outer perimeter of the first transfer film due to a peripheral frame structure of the opening.

The film mounting member may include a first mounting frame on which the fixing frame is seated, and a second mounting frame configured to press and secure a portion of a front surface and an outer perimeter of the fixing frame seated on the first mounting frame.

The first mounting frame may include a circular or polygonal panel or frame defining an opening, and is mounted on or inside a housing, wherein the second mounting frame includes a circular or polygonal panel or frame defining an opening, and is configured to overlap the first mounting frame with the fixing frame therebetween.

The stretching processing member may include a plate-shaped frame of a disk shape or polygonal shape, an elastic press on a front surface of the plate-shaped frame, and a transfer driving member configured to stretch the first transfer film with the elastic press and the plate-shaped frame by supporting a rear surface of the plate-shaped frame, and by moving the plate-shaped frame in a forward direction from the rear surface of the first transfer film toward a front surface of the first transfer film.

The elastic press may include a convex shape of a front surface having curvature, and a substantially flat rear surface on the front surface of the plate-shaped frame.

The convex shape of the elastic press may correspond to at least one of a size or diameter of the first transfer film, an arrangement width or arrangement interval of the light emitting elements, or a stretching width of the first transfer film.

The transfer processing member may be configured to move in a direction of the first transfer film stretched by the stretching processing member in a state in which the support film or the second transfer film is mounted, and is configured to adhere the light emitting elements to the support film or to the second transfer film, wherein the light emitting elements are configured to transfer to the support film or to the second transfer film in a process of detachment away from the first transfer film.

The transfer processing member may include first and second frame binding units configured to secure an outer perimeter of a mask frame by pressing the outer perimeter of the mask frame, a film binding unit assembled to a rear surface of the second frame binding unit to secure the support film or the second transfer film to a rear surface of the mask frame, and a frame fixing unit assembled to a rear surface of the film binding unit to secure a pressing frame to a rear surface of the support film or the second transfer film.

The first and second frame binding units may include a circular or polygonal panel or frame structure having an opening, overlap each other with the mask frame therebetween, and are configured to press and secure partial areas of front and rear surfaces and an outer perimeter of the mask frame.

The mask frame may include a cutting line portion corresponding to a cutting cover area of a second support film corresponding to a cutting area of the display panel for covering the light emitting elements such that they are not attached to the cutting cover area of the second support film, transmission openings respectively corresponding to emission areas of the display panel or front surface areas of the display panel excluding a cutting area, and a blocking portion corresponding to a non-emission area of the display panel.

The frame fixing unit may include a circular or polygonal panel or frame structure having an opening, overlaps the rear surface of the film binding unit with the pressing frame therebetween, and is configured to press and secure partial areas of front and rear surfaces and an outer perimeter of the pressing frame.

The pressing frame may include protruding pressing portions formed such that areas corresponding to transmission openings of the mask frame and emission areas of the display panel protrude in a right-angled or curved shape, and a support frame configured to support rear surfaces of the protruding pressing portions.

According to one or more embodiments of the disclosure, a fabricating method of a display panel includes fabricating a display substrate including pixel circuits and pixel electrodes, fabricating light emitting elements on a base substrate, moving and transferring the light emitting elements to a first transfer film, fixing an outer perimeter of the first transfer film with a fixing frame, mounting the fixing frame to a film mounting member, primarily stretching a width of the first transfer film by pressing a rear surface of the first transfer film with a stretching processing member, and transferring the light emitting elements having an interval changed due to the stretching to a support film or a second transfer film mounted on a transfer processing member.

The fabricating method may further include fixing an outer perimeter of the second transfer film, to which the light emitting elements are transferred, with the fixing frame, mounting the fixing frame on the film mounting member, secondarily stretching the second transfer film by pressing a rear surface of the second transfer film with the stretching processing member, transferring the light emitting elements having another interval changed due to the secondarily stretching the second transfer film to the support film mounted on the transfer processing member, and locating the light emitting elements transferred to the support film on the pixel electrodes of the display substrate.

The transferring of the light emitting elements to the support film or to the second transfer film mounted on the transfer processing member may include fixing a mask frame to first and second frame binding units of the transfer processing member, fixing the support film or the second transfer film with a film binding unit assembled to a rear surface of the second frame binding unit, fixing a pressing frame with a frame fixing unit assembled to a rear surface of the film binding unit, and moving the transfer processing member including the first and second frame binding units, the film binding unit, and the frame fixing unit to bring the support film or the second transfer film into contact with the light emitting elements.

The fixing of the mask frame to the first and second frame binding units may include locating the mask frame between the first and second frame binding units including a circular or polygonal panel or frame structure having an opening, and fixing partial areas of front and rear surfaces and an outer perimeter of the mask frame by overlapping the first and second frame binding units with the mask frame therebetween.

The fixing of the support film or the second transfer film with the film binding unit may include locating the support film or the second transfer film between the second frame binding unit and the pressing frame, and fixing the support film or the second transfer film by overlapping the film binding unit with the rear surface of the second frame binding unit with the support film or the second transfer film therebetween.

The fixing of the pressing frame with the frame fixing unit assembled to the rear surface of the film binding unit may include locating the pressing frame between the film binding unit and the frame fixing unit, and fixing the support film or the second transfer film by overlapping the frame fixing unit with the rear surface of the film binding unit with the pressing frame therebetween.

According to the apparatus for fabricating a display device according to the embodiments, the fabricating cost of the inorganic light emitting diodes may be reduced by varying the arrangement interval of the fabricated inorganic light emitting diodes, and by locating the inorganic light emitting diodes on the substrate of the display panel.

In addition, by precisely locating the inorganic light emitting diodes on the substrate of the display panel by reducing or minimizing the defect rate, it is possible to increase fabricating efficiency of the display panel, and to improve reliability.

However, the aspects of the present disclosure are not limited to the aforementioned aspects, and various other aspects are included in the present specification.

### BRIEF DESCRIPTION OF THE DRAWINGS

The above and other aspects of the present disclosure will become more apparent by describing in detail embodiments thereof with reference to the attached drawings, in which:

FIG. 1 is a plan view of a display device according to one or more embodiments;

FIG. 2 is a plan view schematically illustrating an emission area of each pixel according to one or more embodiments;

FIG. 3 is a plan view schematically illustrating an emission area of each pixel according to one or more other embodiments;

FIG. 4 is an equivalent circuit diagram of each pixel for each of pixels according to one or more embodiments;

FIG. 5 is an equivalent circuit diagram of each of pixels according to one or more other embodiments;

FIG. 6 is a cross-sectional view schematically illustrating a cross section A-A′ of FIG. 2 according to one or more embodiments;

FIG. 7 is an enlarged view schematically illustrating the first emission area of FIG. 6;

FIG. 8 is a cross-sectional view illustrating the light emitting element of FIG. 7;

FIG. 9 is a cross-sectional view schematically illustrating a cross section A-A′ of FIG. 2 according to one or more other embodiments;

FIG. 10 is a cross-sectional view schematically illustrating a cross section A-A′ of FIG. 2 according to one or more other embodiments;

FIG. 11 is a perspective view schematically illustrating an apparatus for fabricating a display panel according to one or more embodiments;

FIG. 12 is another perspective view illustrating the fabricating apparatus illustrated in FIG. 11 in another form;

FIG. 13 is a cross-sectional view illustrating a film mounting member, a stretching processing member, and a transfer processing member illustrated in FIGS. 11 and 12;

FIG. 14 is an exploded perspective view illustrating another form of the film mounting member illustrated in FIG. 13;

FIG. 15 is a flowchart illustrating a fabricating method of a display panel using the fabricating apparatus of FIGS. 11 and 12;

FIGS. 16 to 21 are cross-sectional views for explaining a fabricating method of a light emitting element according to one or more embodiments;

FIG. 22 is a plan view schematically illustrating a first transfer film on which light emitting elements fabricated according to one or more embodiments are arranged;

FIG. 23 is a perspective view schematically illustrating a form in which the first transfer film illustrated in FIG. 22 is mounted on a film mounting member;

FIG. 24 is a front view (e.g., plan view) schematically partially illustrating an arrangement shape of light emitting elements arranged on the first transfer film illustrated in FIG. 22;

FIGS. 25 to 29 are cross-sectional views and front views for explaining the stretching method of the first transfer film;

FIGS. 30 to 38 are various views for explaining the stretching method of the second transfer film;

FIGS. 39 to 41 are cross-sectional views illustrating a method for fabricating a display panel according to one or more embodiments;

FIG. 42 is an diagram illustrating a smart device including a display panel according to one or more embodiments;

FIG. 43 is an diagram illustrating a virtual reality device including a display panel according to one or more embodiments;

FIG. 44 is one diagram illustrating a vehicle including a display panel according to one or more embodiments; and

FIG. 45 is an diagram illustrating a transparent display device including a display panel according to one or more embodiments.

### DETAILED DESCRIPTION

Aspects of some embodiments of the present disclosure and methods of accomplishing the same may be understood more readily by reference to the detailed description of embodiments and the accompanying drawings. Hereinafter, embodiments will be described in more detail with reference to the accompanying drawings. The described embodiments, however, may have various modifications and may be embodied in various different forms, and should not be construed as being limited to only the illustrated embodiments herein. Rather, these embodiments are provided as examples so that this disclosure will be thorough and complete, and will fully convey the aspects of the present disclosure to those skilled in the art, and it should be understood that the present disclosure covers all the modifications, equivalents, and replacements within the idea and technical scope of the present disclosure. Accordingly, processes, elements, and techniques that are not necessary to those having ordinary skill in the art for a complete understanding of the aspects of the present disclosure may not be described.

Unless otherwise noted, like reference numerals, characters, or combinations thereof denote like elements throughout the attached drawings and the written description, and thus, descriptions thereof will not be repeated. Further, parts that are not related to, or that are irrelevant to, the description of the embodiments might not be shown to make the description clear.

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the particular illustrated shapes of regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Thus, the regions illustrated in the drawings are schematic in nature and their shapes are not intended to illustrate the actual shape of a region of a device and are not intended to be limiting. Additionally, as those skilled in the art would realize, the described embodiments may be modified in various different ways, all without departing from the spirit or scope of the present disclosure.

In the detailed description, for the purposes of explanation, numerous specific details are set forth to provide a thorough understanding of various embodiments. It is apparent, however, that various embodiments may be practiced without these specific details or with one or more equivalent arrangements. In other instances, well-known structures and devices are shown in block diagram form in order to avoid unnecessarily obscuring various embodiments.

Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, in this specification, the phrase “on a plane,” or “plan view,” means viewing a target portion from the top, and the phrase “on a cross-section” means viewing a cross-section formed by vertically cutting a target portion from the side.

It will be understood that when an element, layer, region, or component is referred to as being “formed on,” “on,” “connected to,” or “coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled,” or “directly on,” refers to one component directly connecting or coupling another component, or being on another component, without an intermediate component. Meanwhile, other expressions describing relationships between components such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

For the purposes of this disclosure, expressions such as “at least one of,” when preceding a list of elements, modify the entire list of elements and do not modify the individual elements of the list. For example, “at least one of X, Y, and Z,” “at least one of X, Y, or Z,” and “at least one selected from the group consisting of X, Y, and Z” may be construed as X only, Y only, Z only, any combination of two or more of X, Y, and Z, such as, for instance, XYZ, XYY, YZ, and ZZ, or any variation thereof. Similarly, the expression such as “at least one of A and B” may include A, B, or A and B. As used herein, “or” generally means “and/or,” and the term “and/or” includes any and all combinations of one or more of the associated listed items. For example, the expression such as “A and/or B” may include A, B, or A and B.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing particular embodiments only and is not intended to be limiting of the present disclosure. As used herein, the singular forms “a” and “an” are intended to include the plural forms as well, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

The electronic or electric devices and/or any other relevant devices or components according to embodiments of the present disclosure described herein may be implemented utilizing any suitable hardware, firmware (e.g., an application-specific integrated circuit), software, or a combination of software, firmware, and hardware, to process data or digital signals. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate. Circuit hardware may include, for example, application specific integrated circuits (ASICs), general purpose or special purpose central processing units (CPUs) that is configured to execute instructions stored in a non-transitory storage medium, digital signal processors (DSPs), graphics processing units (GPUs), and programmable logic devices such as field programmable gate arrays (FPGAs).

Further, the various components of these devices may be a process or thread, running on one or more processors, in one or more computing devices, executing computer program instructions and interacting with other system components for performing the various functionalities described herein. The computer program instructions are stored in a memory that may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the spirit and scope of the embodiments of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

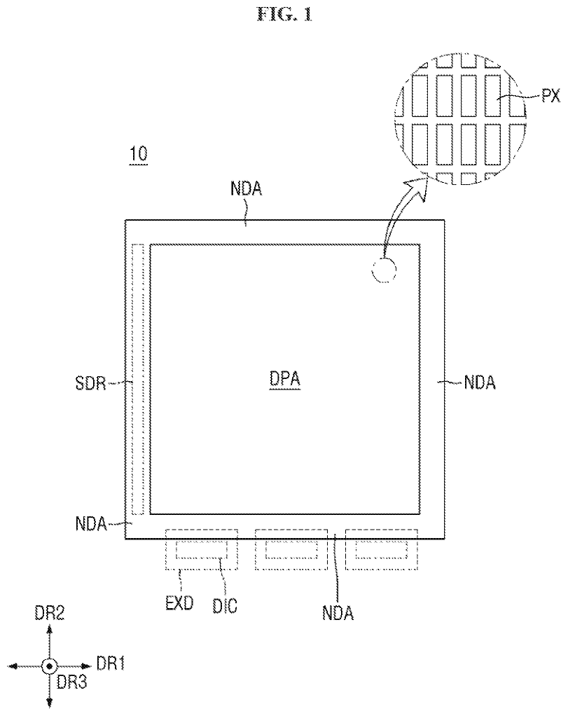

FIG. 1 is a plan view of a display device according to one or more embodiments.

Referring to FIG. 1, a display device 10 according to one or more embodiments may be applied to a smartphone, a mobile phone, a tablet PC, a personal digital assistant (PDA), a portable multimedia player (PMP), a television, a game machine, a wristwatch-type electronic device, a head-mounted display, a monitor of a personal computer, a laptop computer, a car navigation system, a car's dashboard, a digital camera, a camcorder, an external billboard, an electronic billboard, a medical device, an inspection device, various household appliances such as a refrigerator and a washing machine, or an Internet-of-Things device. Herein, a television (TV) is described as an example of a display device, and the TV may have a high resolution or an ultra-high resolution such as HD, UHD, 4K and 8K.

In addition, the display device 10 according to one or more embodiments may be classified into various types according to a display method. Examples of the display device may include an organic light emitting display (OLED) device, an inorganic light emitting display (inorganic EL) device, a quantum dot light emitting display (QED) device, a micro-LED display device, a nano-LED display device, a plasma display device (PDP), a field emission display (FED) device and a cathode ray tube (CRT) display device, a liquid crystal display (LCD) device, an electrophoretic display (EPD) device, and the like. Hereinafter, the micro-LED display device will be described as an example of the display device, and the micro-LED display device applied to the disclosed embodiments will be simply referred to as a display device unless special distinction is required. However, the present disclosure is not limited to the micro-LED display device, and other display devices mentioned above or known in the art may be applied within the same scope of technical spirit.

In addition, in the drawings, a first direction DR1 indicates a horizontal direction of the display device 10, a second direction DR2 indicates a vertical direction of the display device 10, and a third direction DR3 indicates a thickness direction of the display device 10. In this case, “left,” “right,” “upper,” and “lower” indicate directions when the display device 10 is viewed from above. For example, “right side” indicates one side of the first direction DR1, “left side” indicates the other side of the first direction DR1, “upper side” indicates one side of the second direction DR2, and “lower side” indicates the other side of the second direction DR2. Further, “above” indicates one side in the third direction DR3, and “below” indicates the other side in the third direction DR3.

The display device 10 according to one or more embodiments may have a circular shape, an elliptical shape, or a square shape in plan view, for example, a regular tetragonal shape. In addition, when the display device 10 is a television, it may have a rectangular shape with a long side positioned in the horizontal direction. However, the present disclosure is not limited thereto, and the long side of the display device 10 may extend in a vertical direction. Alternatively, the display device 10 may be installed to be rotatable such that its long side is variably positioned to extend in the horizontal or vertical direction.

The display device 10 may include the display area DPA and a non-display area NDA. The display area DPA may be an active area in which an image is displayed. The display area DPA may have a square shape in plan view similar to the overall shape of the display device 10, but is not limited thereto and may have a circular shape or an elliptical shape.

The display area DPA may include a plurality of pixels PX. The plurality of pixels PX may be arranged in a matrix. The shape of each pixel PX may be rectangular or square in plan view. However, without being limited thereto, each pixel PX may have a rhombic shape of which each side is inclined with respect to one side direction of the display device 10. The pixels PX may include multiple color pixels PX. For example, the pixels PX may include, a first color pixel PX of red, a second color pixel PX of green, and a third color pixel PX of blue, although the present disclosure is not limited thereto. The color pixels PX may be alternately arranged in a stripe type or an RGBG type (e.g., a PENTILE™ matrix structure, a PENTILE™ structure, or an RGBG structure, PENTILE™ being a registered trademark of Samsung Display Co., Ltd., Republic of Korea).

The non-display area NDA may be located around the display area DPA. The non-display area NDA may completely or partially surround the display area DPA. The display area DPA may have various shapes such as a circle shape or a square shape. The non-display area NDA may be formed to surround the periphery of the display area DPA. The non-display area NDA may be configured as a bezel of the display device 10.

In the non-display area NDA, a driving circuit or a driving element for driving the display area DPA may be located. In one or more embodiments, in the non-display area NDA located adjacent to a first side (lower side in FIG. 1) of the display device 10, a pad portion may be provided on a display substrate of the display device 10, and an external device EXD may be mounted on pad electrodes of the pad portion. The external devices EXD may include, for example, a connection film, a printed circuit board, a driver integrated circuit (DIC), a connector, a wiring connection film, and the like. A scan driver SDR directly formed on the display substrate of the display device 10 may be provided in the non-display area NDA located adjacent to a second side (left side in FIG. 1) of the display device 10.

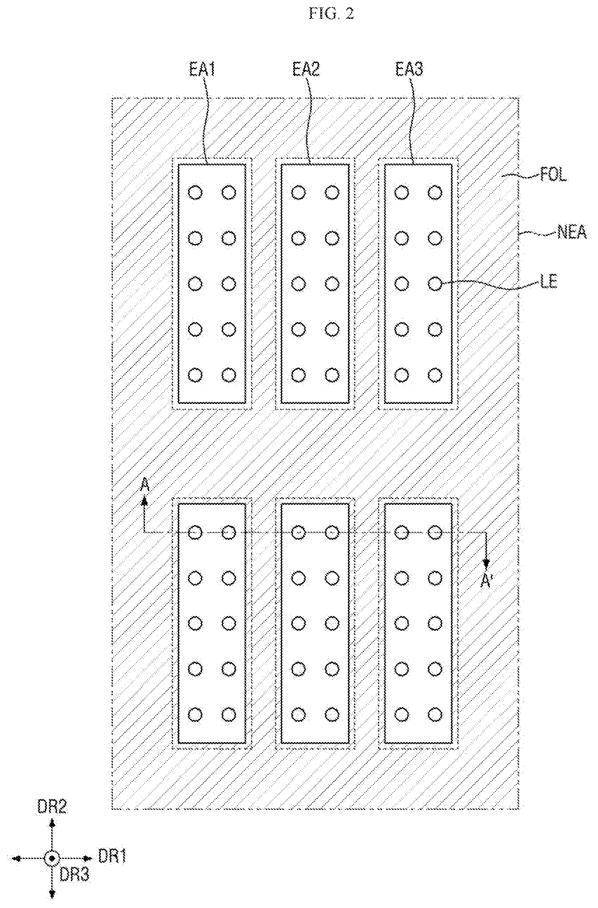

FIG. 2 is a plan view schematically illustrating an emission area of each pixel according to one or more embodiments.

Referring to FIG. 2, the plurality of pixels PX may be arranged in a matrix direction, and the plurality of pixels PX may be divided into a first color pixel PX of a red color, a second color pixel PX of a green color, and a third color pixel PX of a blue color. In addition, a fourth color pixel PX of a white color may be further included.

The pixel electrode of the first color pixel PX may be positioned in a first emission area EA1, but at least a part thereof may extend to a non-emission area NEA. The pixel electrode of the second color pixel PX may be positioned in a second emission area EA2, but at least a part thereof may extend to the non-emission area NEA. The pixel electrode of the third color pixel PX may be positioned in a third emission area EA3, but at least a part thereof may extend to the non-emission area NEA. A pixel electrode of each pixel PX may penetrate at least one layer of the insulating layers to be connected to any one switching element included in each pixel circuit.

A plurality of light emitting elements LE are respectively located on the pixel electrode of the first emission area EA1, the pixel electrode of the second emission area EA2, and the pixel electrode of the third emission area EA3. That is, a respective light emitting element LE is located in each of the first emission area EA1, the second emission area EA2, and the third emission area EA3. In addition, a first color filter of a red color, a second color filter of a green color, and a third color filter of a blue color may be located on the first emission area EA1, the second emission area EA2, and the third emission area EA3 in which the plurality of light emitting elements LE are located, respectively. A first organic layer FOL may be located in the non-emission area NEA.

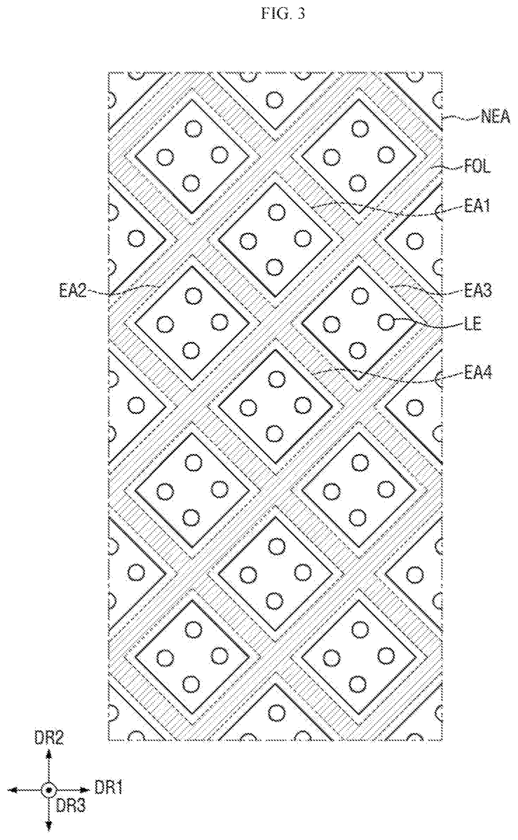

FIG. 3 is a plan view schematically illustrating an emission area of each pixel according to one or more other embodiments.

Referring to FIG. 3, the shape of each pixel PX is not limited to a rectangular shape or a square shape in plan view, and each side of the pixel PX may have a rhombus shape inclined with respect to one side direction of the display device 10 to form a PENTILE™ structure. Accordingly, in each of the pixels PX of the PENTILE™ structure, the first emission area EA1 of the first color pixel PX, the second emission area EA2 of the second color pixel PX, the third emission area EA3 of the third color pixel PX, and the fourth emission area EA4 of the pixel PX of any one color of the first to third colors may each be formed in a rhombus shape.

The first to fourth emission areas EA1 to EA4 of each pixel PX may be the same or different in size or planar area. Likewise, the number of light emitting elements LE formed in each of the first to fourth emission areas EA1 to EA4 may be the same or different.

The area of the first emission area EA1, the area of the second emission area EA2, the area of the third emission area EA3, and the area of the fourth emission area EA4 may be substantially the same, but are not limited thereto and may be different from each other. The distance between the first emission area EA1 and the second emission area EA2 that are adjacent to each other, the distance between the second emission area EA2 and the third emission area EA3 that are adjacent to each other, the distance between the first emission area EA1 and the third emission area EA3 that are adjacent to each other, and the distance between the third emission area EA3 and the fourth emission area EA4 that are adjacent to each other may be substantially the same, or one or more may be different from the others.

In addition, the first emission area EA1 may emit the first light, the second emission area EA2 may emit the second light, and the third emission area EA3 and the fourth emission area EA4 may emit the third light, but the present specification is not limited thereto. For example, the first emission area EA1 may emit the second light, the second emission area EA2 may emit the first light, and the third and fourth emission areas EA3 and EA4 may emit the third light. Alternatively, the first emission area EA1 may emit the third light, the second emission area EA2 may emit the second light, and the third and fourth emission areas EA3 and EA4 may emit the first light. Alternatively, at least one emission area of the first to fourth emission areas EA1 to EA4 may emit the fourth light. The fourth light may be light of a yellow wavelength band. That is, the main peak wavelength of the fourth light may be positioned at about 550 nm to about 600 nm, but the present specification is not limited thereto.

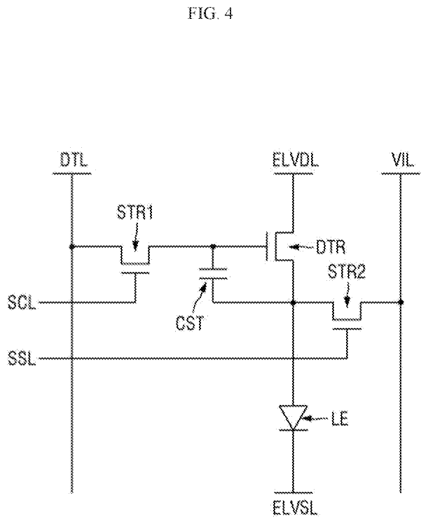

FIG. 4 is an equivalent circuit diagram of each pixel for each of pixels according to one or more embodiments.

Referring to FIG. 4, each pixel PX may include three transistors DTR, STR1, and STR2 for light emission of the light emitting elements LE, and one capacitor CST for storage. A driving transistor DTR adjusts a current flowing from a first power supply line ELVDL, to which the first power voltage is supplied, to any one light emitting element LE according to a voltage difference between the gate electrode and the source electrode. The gate electrode of the driving transistor DTR may be connected to the first electrode of a first transistor ST1, the source electrode thereof may be connected to the first electrode of any one light emitting element LE, and the drain electrode thereof may be connected to the first power supply line ELVDL to which the first power voltage is applied.

A first transistor STR1 is turned on by the scan signal of a scan line SCL to connect a data line DTL to the gate electrode of the driving transistor DTR. The gate electrode of the first transistor STR1 may be connected to the scan line SL, the first electrode thereof may be connected to the gate electrode of the driving transistor DTR, and the second electrode thereof may be connected to the data line DTL.

A second transistor STR2 is turned on by the sensing signal of a sensing signal line SSL to connect an initialization voltage line VIL to the source electrode of the driving transistor DTR. The gate electrode of the second transistor ST2 may be connected to the sensing signal line SSL, the first electrode thereof may be connected to the initialization voltage line VIL, and the second electrode thereof may be connected to the source electrode of the driving transistor DTR.

In one or more embodiments, the first electrode of each of the first and second transistors STR1 and STR2 may be a source electrode, and the second electrode thereof may be a drain electrode, but the present disclosure is not limited thereto, and may be vice versa.

The capacitor CST is formed between the gate electrode and the source electrode of the driving transistor DTR. The storage capacitor CST stores a voltage difference between a gate voltage and a source voltage of the driving transistor DTR.

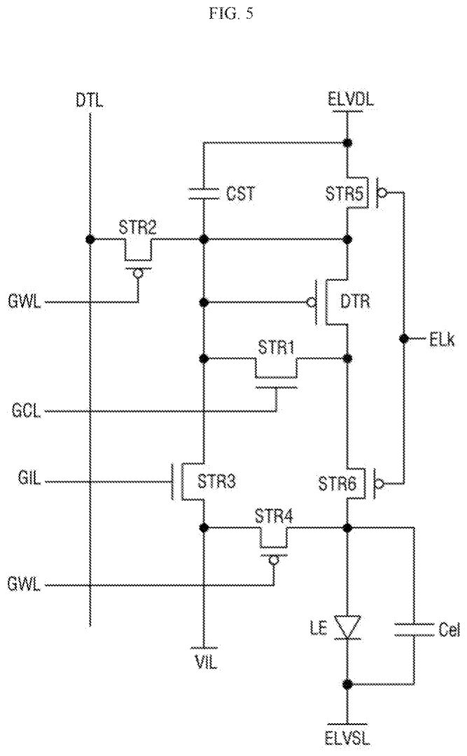

The driving transistor DTR, the first transistor STR1, and the second transistor STR2 may be formed as thin film transistors. Further, in the description of FIG. 5, it is assumed that the driving transistor DTR, the first switching transistor STR1, and the second switching transistor STR2 are N-type metal oxide semiconductor field effect transistors (MOSFETs), but the present disclosure is not limited thereto. That is, the driving transistor DTR, the first switching transistor STR1, and the second switching transistor STR2 may be P-type MOSFETs, or some of the driving transistor DTR, the first switching transistor STR1, and the second switching transistor STR2 may be N-type MOSFETs, while others may be P-type MOSFETs.

FIG. 5 is an equivalent circuit diagram of each of pixels according to one or more other embodiments.

Referring to FIG. 5, each pixel PX may include three transistors DTR, STR1, and STR2 for light emission of the light emitting elements LE, and one capacitor CST for storage. The driving transistor DTR, switch elements, and the capacitor CST are included. The switch elements may include first to sixth transistors STR1, STR2, STR3, STR4, STRS, and STR6.

The driving transistor DTR includes a gate electrode, a first electrode, and a second electrode. The driving transistor DTR controls a drain-source current (hereinafter, referred to as “driving current”) flowing between the first electrode and the second electrode according to a data voltage applied to the gate electrode.

The capacitor CST is formed between the second electrode of the driving transistor DTR and a first power line ELVDL. One electrode of the capacitor CST may be connected to the second electrode of the driving transistor DTR, and the other electrode thereof may be connected to the first power line ELVDL.

When the first electrode of each of the driving transistor DTR and the first to sixth transistors STR1 to STR6 is a source electrode, the second electrode thereof may be a drain electrode. Alternatively, when the first electrode of each of the driving transistor DTR and the first to sixth transistors STR1 to STR6 is a drain electrode, the second electrode thereof may be a source electrode.

The driving transistor DTR, the second transistor STR2, the fourth transistor STR4, the fifth transistor STRS, and the sixth transistor STR6 may be configured as P-type metal oxide semiconductor field effect transistors (MOSFETs), and the first transistor STR1 and the third transistor STR3 may be configured as N-type MOSFETs. Alternatively, the first to sixth transistors STR1, STR2, STR3, STR4, STR5, STR6, and the driving transistor DTR may be formed of a P-type metal oxide semiconductor field effect transistor (MOSFET).

It should be noted that the equivalent circuit diagram of the pixel according to the description above is not limited to those illustrated in FIGS. 4 and 5. The equivalent circuit diagram of the pixel according to the present specification may be formed in other known circuit structures that those skilled in the art may employ in addition to the embodiments illustrated in FIGS. 4 and 5.

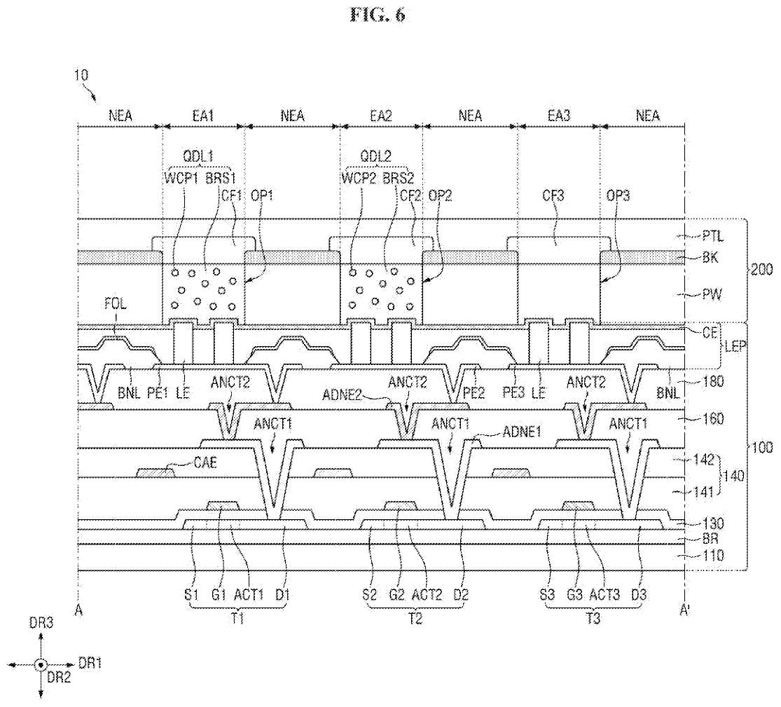

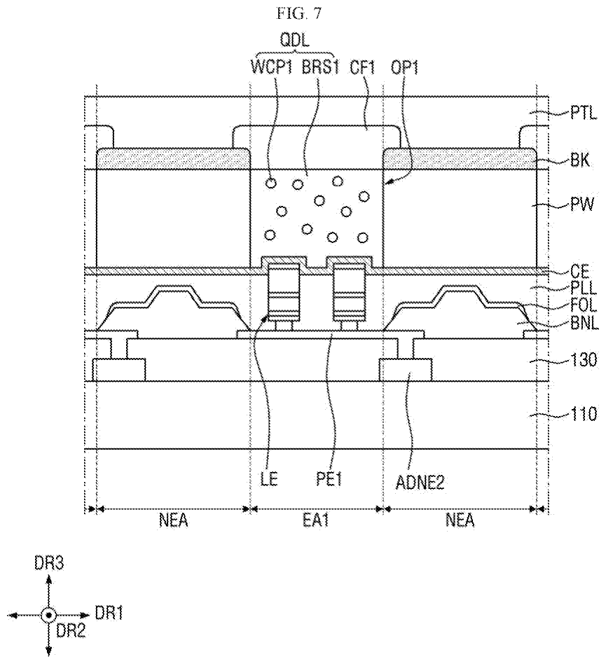

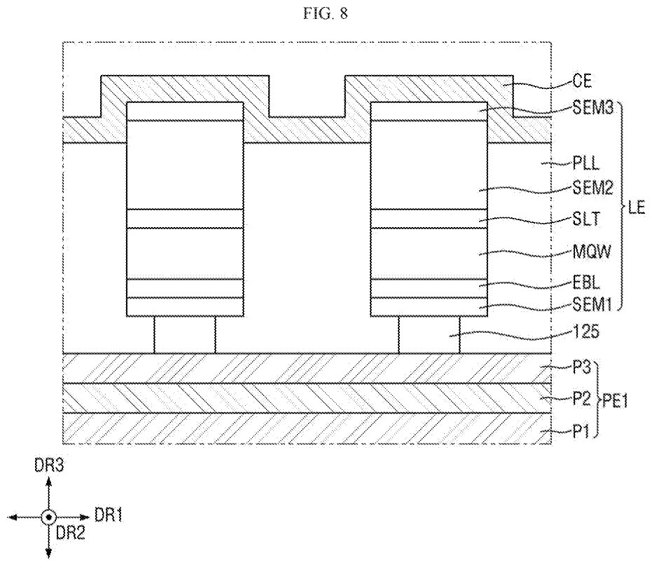

FIG. 6 is a cross-sectional view schematically illustrating a cross section A-A′ of FIG. 2 according to one or more embodiments. Further, FIG. 7 is an enlarged view schematically illustrating the first emission area of FIG. 6, and FIG. 8 is a cross-sectional view illustrating the light emitting element of FIG. 7.

Referring to FIGS. 6 to 8, the display panel of the display device 10 may include a display substrate 100, and a wavelength conversion member 200 located on the display substrate 100.

A barrier layer BR may be located on a first substrate 110 of the display substrate 100. The first substrate 110 may be formed of an insulating material such as a polymer resin. For example, the first substrate 110 may be formed of polyimide. The first substrate 110 may be a flexible substrate which can be bent, folded or rolled.

The barrier layer BR is a layer for protecting thin film transistors T1, T2, and T3 and a light emitting element unit LEP from moisture permeating through the first substrate 110, which may be relatively susceptible to moisture permeation. The barrier layer BR may be formed as a plurality of inorganic layers that are alternately stacked. For example, the barrier layer BR may be formed of multiple layers in which one or more inorganic layers of a silicon nitride layer, a silicon oxynitride layer, a silicon oxide layer, a titanium oxide layer, and an aluminum oxide layer are alternately stacked.

Each of the thin film transistors T1, T2, and T3 may be located on the barrier layer BR. Each of the thin film transistors T1, T2, and T3 includes an active layer ACT1/ACT2/ACT3, a gate electrode G1/G2/G3, a source electrode S1/S2/S3, and a drain electrode D1/D2/D3.

The active layer, the source electrode, and the drain electrode of the thin film transistors T1, T2, and T3 may be located on the barrier layer BR. The active layer of the thin film transistors T1, T2, and T3 includes polycrystalline silicon, monocrystalline silicon, low-temperature polycrystalline silicon, amorphous silicon, or an oxide semiconductor. Referring to a first thin film transistor T1, the active layer ACT1 overlapping the gate electrode G1 in the third direction (Z-axis direction) that is the thickness direction of the first substrate 110 may be defined as a channel region. The source electrode S1 and the drain electrode D1 that do not overlap the gate electrode G1 in the third direction (Z-axis direction) may have conductivity by doping a silicon semiconductor or an oxide semiconductor with ions or impurities.

The gate insulating layer 130 may be located on the active layer, the source electrode, and the drain electrode of the thin film transistors T1, T2, and T3. The gate insulating layer 130 may be formed of an inorganic layer, for example, a silicon nitride layer, a silicon oxynitride layer, a silicon oxide layer, a titanium oxide layer, or an aluminum oxide layer.

The gate electrode of the thin film transistors T1, T2, and T3 may be arranged on the gate insulating layer 130. The gate electrode may overlap the active layer in the third direction (Z-axis direction). The gate electrode may be formed as a single layer or multiple layers made of any one of molybdenum (Mo), aluminum (Al), chromium (Cr), gold (Au), titanium (Ti), nickel (Ni), neodymium (Nd) and copper (Cu) or an alloy thereof.

A first interlayer insulating layer 141 may be located on the gate electrode of the thin film transistors T1, T2, and T3. The first interlayer insulating layer 141 may be formed of an inorganic layer, for example, a silicon nitride layer, a silicon oxynitride layer, a silicon oxide layer, a titanium oxide layer, or an aluminum oxide layer. The first interlayer insulating layer 141 may be formed of a plurality of inorganic layers.

A capacitor electrode CAE may be located on the first interlayer insulating layer 141. The capacitor electrode CAE may overlap the gate electrode G1 of the thin film transistors T1, T2, and T3 in the third direction (Z-axis direction). Because the first interlayer insulating layer 141 has a dielectric constant (e.g., a predetermined dielectric constant), the capacitor electrode CAE, the corresponding gate electrode, and the first interlayer insulating layer 141 located therebetween may form a capacitor. The capacitor electrode CAE may be formed as a single layer or multiple layers made of any one of molybdenum (Mo), aluminum (Al), chromium (Cr), gold (Au), titanium (Ti), nickel (Ni), neodymium (Nd) and copper (Cu) or an alloy thereof.

A second interlayer insulating layer 142 may be located on the capacitor electrode CAE. The second interlayer insulating layer 142 may be formed of an inorganic layer, for example, a silicon nitride layer, a silicon oxynitride layer, a silicon oxide layer, a titanium oxide layer, or an aluminum oxide layer. The second interlayer insulating layer 142 may be formed of a plurality of inorganic layers.

The first anode connection electrode ADNE1 (e.g., a plurality of first anode connection electrodes) may be located on the second interlayer insulating layer 142. A corresponding first anode connection electrode ADNE1 may be connected to a corresponding drain electrode of a corresponding thin film transistor through a corresponding first connection contact hole ANCT1 penetrating the gate insulating layer 130, the first interlayer insulating layer 141, and the second interlayer insulating layer 142. The first anode connection electrode ADNE1 may be formed as a single layer or as multiple layers made of any one of molybdenum (Mo), aluminum (Al), chromium (Cr), gold (Au), titanium (Ti), nickel (Ni), neodymium (Nd), copper (Cu), and/or an alloy thereof.

A first planarization layer 160 for flattening a stepped portion formed by the thin film transistors T1, T2, and T3 may be located on the first anode connection electrode ADNE1. The first planarization layer 160 may be formed of an organic layer such as acryl resin, epoxy resin, phenolic resin, polyamide resin, polyimide resin, and the like.

A second anode connection electrode ADNE2 (e.g., a plurality of second anode connection electrodes) may be located on the first planarization layer 160. A corresponding second anode connection electrode ADNE2 may be connected to a corresponding first anode connection electrode ADNE1 through a corresponding second connection contact hole ANCT2 penetrating the first planarization layer 160. The second anode connection electrode ADNE2 may be formed as a single layer, or as multiple layers made of any one of molybdenum (Mo), aluminum (Al), chromium (Cr), gold (Au), titanium (Ti), nickel (Ni), neodymium (Nd) and copper (Cu), and/or an alloy thereof.

A second planarization layer 180 may be located on the second anode connection electrode ADNE2. The second planarization layer 180 may be formed of an organic layer, such as acryl resin, epoxy resin, phenolic resin, polyamide resin, polyimide resin, and the like.

The light emitting element unit LEP may be formed on the second planarization layer 180. The light emitting element unit LEP may include a plurality of pixel electrodes PE1, PE2, and PE3, the plurality of light emitting elements LE, and a common electrode CE.

The plurality of pixel electrodes PE1, PE2, and PE3 may include the first pixel electrode PE1, the second pixel electrode PE2, and the third pixel electrode PE3. The first pixel electrode PE1, the second pixel electrode PE2, and the third pixel electrode PE3 may serve as a first electrode of the light emitting element LE, and may be an anode electrode or a cathode electrode. The first pixel electrode PE1 may be positioned in the first emission area EA1, but at least a part thereof may extend to the non-emission area NEA. The second pixel electrode PE2 may be positioned in the second emission area EA2, but at least a part thereof may extend to the non-emission area NEA. The third pixel electrode PE3 may be positioned in the third emission area EA3, but at least a part thereof may extend to the non-emission area NEA. The first pixel electrode PE1 may penetrate the gate insulating layer 130 to be connected to the first switching element T1, the second pixel electrode PE2 may penetrate the gate insulating layer 130 to be connected to the second switching element T2, and the third pixel electrode PE3 may penetrate the gate insulating layer 130 to be connected to the third switching element T3.

The first pixel electrode PE1, the second pixel electrode PE2, and the third pixel electrode PE3 may be reflective electrodes. The first pixel electrode PE1, the second pixel electrode PE2, and the third pixel electrode PE3 may be formed of titanium (Ti), copper (Cu), and/or an alloy material of titanium (Ti) and/or copper (Cu). In addition, the first pixel electrode PE1, the second pixel electrode PE2, and the third pixel electrode PE3 may have a stacked structure of titanium (Ti) and copper (Cu). In addition, the first pixel electrode PE1, the second pixel electrode PE2, and the third pixel electrode PE3 may have a stacked structure formed by stacking a material layer having a high work function, such as titanium oxide (TiO₂), indium tin oxide (ITO), indium zinc oxide (IZO), zinc oxide (ZnO), indium tin zinc oxide (ITZO), or magnesium oxide (MgO), and a reflective material layer such as silver (Ag), magnesium (Mg), aluminum (Al), platinum (Pt), lead (Pb), gold (Au), nickel (Ni), neodymium (Nd), iridium (Ir), chromium (Cr), lithium (Li), calcium (Ca), Titanium (Ti), copper (Cu), or a mixture thereof. The material layer having a high work function may be located above the reflective material layer, and may be located closer to the light emitting element LE. The first pixel electrode PE1, the second pixel electrode PE2, and the third pixel electrode PE3 may have a multilayer structure of ITO/Mg, ITO/MgF, ITO/Ag, and ITO/Ag/ITO, but are not limited thereto.

A bank BNL may be positioned on the first pixel electrode PE1, the second pixel electrode PE2, and the third pixel electrode PE3. The bank BNL may include an opening exposing the first pixel electrode PE1, an opening exposing the second pixel electrode PE2, and an opening exposing the third pixel electrode PE3, and may define the first emission area EA1, the second emission area EA2, the third emission area EA3, and the non-emission area NEA. That is, an area of the first pixel electrode PE1 that is not covered by the bank BNL, and that is exposed, may be the first emission area EA1. An area of the second pixel electrode PE2 that is not covered by the bank BNL and that is exposed may be the second emission area EA2. An area of the third pixel electrode PE3 that is not covered by the bank BNL and that is exposed may be the third emission area EA3. In addition, an area in which the bank BNL is positioned may be the non-emission area NEA.

The bank BNL may include an inorganic insulating material, for example, acrylic resin, epoxy resin, phenolic resin, polyamide resin, polyimide resin, unsaturated polyester resin, polyphenylene resin, polyphenylenesulfide resin, benzocyclobutene (BCB), or the like.

In one or more embodiments, the bank BNL may overlap the color filters CF1, CF2, and CF3 and a light blocking member BK of the wavelength conversion member 200, which will be described later. In one or more embodiments, the bank BNL may completely overlap the light blocking member BK. In addition, the bank BNL may overlap the first color filter CF1, the second color filter CF2, and the third color filter CF3.

The plurality of light emitting elements LE may be located on the first pixel electrode PE1, the second pixel electrode PE2, and the third pixel electrode PE3.

As illustrated in FIGS. 7 and 8, one or more respective light emitting elements LE may be located in each of the first emission area EA1, the second emission area EA2, and the third emission area EA3. The light emitting element LE may be a vertical light emitting diode element elongated in the third direction DR3. That is, the length of the light emitting element LE in the third direction DR3 may be longer than the length or width thereof in the horizontal direction. The length or width in the horizontal direction indicates a length in the first direction DR1 or a length in the second direction DR2. For example, the length of the light emitting element LE in the third direction DR3 may be about 1 μm to about 5 μm.

The light emitting element LE may be a micro light emitting diode element. The light emitting element LE may include a connection electrode 125, a first semiconductor layer SEM1, an electron blocking layer EBL, an active layer MQW, a superlattice layer SLT, a second semiconductor layer SEM2, and a third semiconductor layer SEM3, in the thickness direction of the display substrate 100, that is, the third direction DR3. The connection electrode 125, the first semiconductor layer SEM1, the electron blocking layer EBL, the active layer MQW, the superlattice layer SLT, the second semiconductor layer SEM2, and the third semiconductor layer SEM3 may be sequentially stacked in the third direction DR3.

In some embodiments, the light emitting element LE may have a cylindrical shape that is longer in width than in height, a disc shape, or a rod shape. However, the present disclosure is not limited thereto, and the light emitting element LE may have various shapes, such as a rod shape, a wire shape, a tube shape, a polygonal prism shape such as a regular cube, a rectangular parallelepiped and a hexagonal prism, or a shape extending in one direction and having a partially inclined outer surface.

A respective connection electrode 125 may be located on each of the plurality of pixel electrodes PE1, PE2, and PE3. Hereinafter, the light emitting element LE located on the first pixel electrode PE1 will be described as an example.

The connection electrode 125 may serve to apply an emission signal to the light emitting element LE by being adhered to the first pixel electrode PE1. The connection electrode 125 may be an ohmic connection electrode. However, the present disclosure is not limited thereto, and it may be a Schottky connection electrode. The light emitting element LE may include at least one connection electrode 125. FIGS. 7 and 8 illustrate that the light emitting element LE includes one connection electrode 125, but is not limited thereto. In some cases, the light emitting element LE may include a larger number of connection electrodes 125, or may omit the connection electrode 125. The following description of the light emitting element LE may be equally applied even if the number of connection electrodes 125 is different or further includes other structures.

When the light emitting element LE is electrically connected to the first pixel electrode PE1 in the display device 10 according to one or more embodiments, the connection electrode 125 may reduce the resistance and may improve the adhesion between the light emitting element LE and the first pixel electrode PE1. The connection electrode 125 may include a conductive metal oxide. For example, the connection electrode 125 may be ITO. Because the connection electrode 125 is directly in contact with, and connected to, the lower first pixel electrode PE1, the connection electrode 125 may be made of the same material as the first pixel electrode PE1. In addition, the connection electrode 125 may selectively further include a reflective electrode made of a metal material having a high reflectivity such as aluminum (Al) or a diffusion barrier layer including nickel (Ni). Accordingly, adhesion between the connection electrode 125 and the first pixel electrode PE1 may be improved, and thus a contact characteristic may be increased.

Referring to FIG. 8, in one or more embodiments, the first pixel electrode PE1 may include a lower electrode layer P1, a reflective layer P2, and an upper electrode layer P3. The lower electrode layer P1 may be located at the lowermost portion of the first pixel electrode PE1, and may be electrically connected from the switching element. The lower electrode layer P1 may include a metal oxide, and may include, for example, titanium oxide (TiO₂), indium tin oxide (ITO), indium zinc oxide (IZO), zinc oxide (ZnO), indium tin zinc oxide (ITZO), magnesium oxide (MgO), or the like.

The reflective layer P2 may be located on the lower electrode layer P1 to reflect light emitted from the light emitting element LE upward. The reflective layer P2 may include a metal having high reflectivity, may include, for example, silver (Ag), magnesium (Mg), aluminum (Al), platinum (Pt), lead (Pd), gold (Au), nickel (Ni), neodymium (Nd), iridium (Ir), chromium (Cr), lithium (Li), calcium (Ca), or a mixture thereof.

The upper electrode layer P3 may be located on the reflective layer P2, and may be directly in contact with the light emitting element LE. The upper electrode layer P3 may be located between the reflective layer P2 and the connection electrode 125 of the light emitting element LE, and may be directly in contact with the connection electrode 125. As described above, the connection electrode 125 is made of a metal oxide, and the upper electrode layer P3 may also be made of a metal oxide in the same way as the connection electrode 125.

The upper electrode layer P3 may be formed of titanium (Ti), copper (Cu), or an alloy material of titanium (Ti) and copper (Cu). In addition, it may have a stacked structure of titanium (Ti) and copper (Cu). In addition, the upper electrode layer P3 may include titanium oxide (TiO₂), indium tin oxide (ITO), indium zinc oxide (IZO), zinc oxide (ZnO), indium tin zinc oxide (ITZO), or magnesium oxide (MgO). In one or more embodiments, when the connection electrode 125 is made of ITO, the first pixel electrode PE1 may have a multilayer structure of ITO/Ag/ITO.

The first semiconductor layer SEM1 may be located on the connection electrode 125. The first semiconductor layer SEM1 may be a p-type semiconductor, and may include a semiconductor material having a chemical formula of AlxGayIn1-x-yN (0≤x≤1, 0≤y≤1, 0≤x+y≤1). For example, it may be any one or more of p-type doped AlGaInN, GaN, AlGaN, InGaN, AlN and InN. The first semiconductor layer SEM1 may be doped with a p-type dopant, and the p-type dopant may be Mg, Zn, Ca, Se, Ba, or the like. For example, the first semiconductor layer SEM1 may be p-GaN doped with p-type Mg. The thickness of the first semiconductor layer SEM1 may be in a range of about 30 nm to about 200 nm, but is not limited thereto.

The electron blocking layer EBL may be located on the first semiconductor layer SEM1. The electron blocking layer EBL may be a layer for suppressing or preventing too many electrons from flowing into the active layer MQW. For example, the electron blocking layer EBL may be p-AlGaN doped with p-type Mg. The thickness of the electron blocking layer EBL may be within a range of about 10 nm to 50 about nm, but the present disclosure is not limited thereto. Further, the electron blocking layer EBL may be omitted.

The active layer MQW may be located on the electron blocking layer EBL. The active layer MQW may emit light by coupling of electron-hole pairs according to an electrical signal applied through the first semiconductor layer SEM1 and the second semiconductor layer SEM2.

The active layer MQW may include a material having a single or multiple quantum well structure. When the active layer MQW contains a material having a multiple quantum well structure, the active layer MQW may have the structure in which a plurality of well layers and barrier layers are alternately laminated. At this time, the well layer may be formed of InGaN, and the barrier layer may be formed of GaN or AlGaN, but the present disclosure is not limited thereto. The thickness of the well layer may be about 1 nm to about 4 nm, and the thickness of the barrier layer may be about 3 nm to about 10 nm.

Alternatively, the active layer MQW may have a structure in which semiconductor materials having large band gap energy, and semiconductor materials having small band gap energy, are alternately stacked, and may include other group III to V semiconductor materials according to the wavelength band of the emitted light. The light emitted by the active layer MQW is not limited to the first light, and in some cases, the second light (light of the green wavelength band) or the third light (light of the red wavelength band) may be emitted.

For example, the color of the light emitted from the active layer MQW may vary according to the content of indium (In). For example, as the content of indium (In) decreases, the wavelength band of the light emitted by the active layer may move to the red wavelength band, and as the content of indium (In) increases, the wavelength band of the light emitted by the active layer may move to the blue wavelength band. As one example, when the content of indium (In) is less than about 15%, the active layer MQW may emit the first light in the red wavelength band having a main peak wavelength in a range of about 600 nm to about 750 nm. Alternatively, as one example, when the content of indium (In) is about 25%, the active layer MQW may emit the second light in the green wavelength band having a main peak wavelength in a range of about 480 nm to about 560 nm. In addition, when the content of indium (In) is about 35% or more, the active layer MQW may emit the third light in the blue wavelength band having a main peak wavelength in a range of about 370 nm to about 460 nm. An example in which the active layer MQW emits light in the blue wavelength band having a main peak wavelength of about 370 nm to about 460 nm will be described with reference to FIG. 6.

The superlattice layer SLT may be located on the active layer MQW. The superlattice layer SLT may be a layer for relieving stress between the second semiconductor layer SEM2 and the active layer MQW. For example, the superlattice layer SLT may be formed of InGaN or GaN. The thickness of the superlattice layer SLT may be about 50 nm to about 200 nm. The superlattice layer SLT may be omitted.

The second semiconductor layer SEM2 may be located on the superlattice layer SLT. The second semiconductor layer SEM2 may be an n-type semiconductor. The second semiconductor layer SEM2 may include a semiconductor material having a chemical formula of AlxGayIn1-x-yN (0≤x≤1, 0≤y≤1, 0≤x+y≤1). For example, it may be any one or more of n-type doped AlGaInN, GaN, AlGaN, InGaN, AlN, and InN. The second semiconductor layer SEM2 may be doped with an n-type dopant, and the n-type dopant may be Si, Ge, Sn, or the like. For example, the second semiconductor layer SEM2 may be n-GaN doped with n-type Si. The thickness of the second semiconductor layer SEM2 may be within a range of about 2 μm to about 4 μm, but the present disclosure is not limited thereto.

The third semiconductor layer SEM3 may be located on the second semiconductor layer SEM2. The third semiconductor layer SEM3 may be located between the second semiconductor layer SEM2 and the common electrode CE. The third semiconductor layer SEM3 may be an undoped semiconductor. The third semiconductor layer SEM3 may contain the same material as that of the second semiconductor layer SEM2, and may contain a material that is not doped with an n-type or p-type dopant. In one or more embodiments, the third common semiconductor layer SEM3 may be, but is not limited to, at least one of undoped InAlGaN, GaN, AlGaN, InGaN, AlN, or InN.

A planarization layer PLL may be located on (e.g., above) the bank BNL and the plurality of pixel electrodes PE1, PE2, and PE3. The planarization layer PLL may planarize a lower step so that the common electrode CE, which will be described later, may be formed. The planarization layer PLL may be formed to have a height (e.g., predetermined height) so that at least a part, for example, an upper portion, of the plurality of light emitting elements LE, may protrude above the planarization layer PLL. That is, the height of the planarization layer PLL with respect to the top surface of the first pixel electrode PE1 may be less than, or below, the height of the light emitting element LE.

The planarization layer PLL may include an organic material to planarize the lower step. For example, the planarization layer PLL may include acrylic resin, epoxy resin, phenolic resin, polyamide resin, polyimide resin, unsaturated polyester resin, polyphenylene resin, polyphenylenesulfide resin, benzocyclobutene (BCB), or the like.

The common electrode CE may be located on the planarization layer PLL and the plurality of light emitting elements LE. For example, the common electrode CE may be located on one surface of the first substrate 110 on which the light emitting element LE is formed, and may be located entirely in the display area DA and the non-display area NDA. The common electrode CE overlaps each of the emission areas EA1, EA2, and EA3 in the display area DA, and may be relatively thin to allow light to be emitted.

The common electrode CE may be directly located on the top surface and the side surface of the plurality of light emitting elements LE. The common electrode CE may be directly in contact with the second semiconductor layer SEM2 and the third semiconductor layer SEM3 among the side surfaces of the light emitting element LE. As illustrated in FIG. 6, the common electrode CE may be a common layer that covers the plurality of light emitting elements LE, and that commonly connects the plurality of light emitting elements LE. Because the second semiconductor layer SEM2 having conductivity has a patterned structure in each of the light emitting elements LE, the common electrode CE may be directly in contact with the side surface of the second semiconductor layer SEM2 of each of the light emitting elements LE so that a common voltage may be applied to each of the light emitting elements LE.

Because the common electrode CE is entirely located on the first substrate 110, and because a common voltage is applied, it may be suitable for the common electrode CE to include a material having a low resistance. In addition, the common electrode CE may be formed to be thin to allow light to pass therethrough. For example, the common electrode CE may include a material having a low resistance, such as aluminum (Al), silver (Ag), copper (Cu), or the like. The thickness of the common electrode CE may be about 10 Å to about 200 Å, but is not limited thereto.

The above-described light emitting elements LE may be supplied with a pixel voltage or an anode voltage from a pixel electrode through the connection electrode 125, and may be supplied with a common voltage through the common electrode CE. The light emitting element LE may emit light with a luminance (e.g., predetermined luminance) according to a voltage difference between the pixel voltage and the common voltage.

In some embodiments, by locating the plurality of light emitting elements LE (e.g., inorganic light emitting diodes) on the pixel electrodes PE1, PE2, and PE3, disadvantages of organic light emitting diodes, which are vulnerable to external moisture or oxygen, may be avoided, and lifespan and reliability may be improved.

The first organic layer FOL may be located on the bank BNL located in the non-emission area NEA.

The first organic layer FOL may overlap the non-emission area NEA, and might not to overlap the emission areas EA1, EA2, and EA3. The first organic layer FOL may be located directly on the bank BNL and may be spaced apart from a plurality of adjacent pixel electrodes PE1, PE2, and PE3. The first organic layer FOL may be located entirely on the first substrate 110 (e.g., may be generally located over an entirety of the first substrate 110), and may surround the plurality of emission areas EA1, EA2, and EA3. The first organic layer FOL may be entirely lattice shaped.

The first organic layer FOL may serve to enable suitable detachment of the plurality of light emitting elements LE that are initially in contact with the first organic layer FOL, which is the non-emission area NEA, as will be described in a fabricating process to be described later. For example, when laser light is irradiated, the first organic layer FOL absorbs energy and rapidly (e.g., instantaneously) increases its temperature to be ablated. Accordingly, the plurality of light emitting elements LE in contact with the top surface of the first organic layer FOL may be detached from the top surface of the first organic layer FOL.

The first organic layer FOL may include a polyimide-based compound. The polyimide-based compound of the first organic layer FOL may include a cyano group to absorb light having a wavelength of about 308 nm, for example, laser light. In one or more embodiments, each of the first organic layer FOL and the bank BNL may include a polyimide-based compound, but may include different polyimide-based compounds. For example, the bank BNL may be formed of a polyimide-based compound not including a cyano group, and the first organic layer FOL may be formed of a polyimide-based compound including a cyano group. For laser light having a wavelength of about 308 nm, the transmittance of the first organic layer FOL may be less than the transmittance of the bank BNL, the transmittance of the bank BNL being about 60% or more, and the transmittance of the first organic layer FOL being near 0%. In addition, the absorption rate of the first organic layer FOL with respect to laser light having a wavelength of about 308 nm may be almost 100%. The first organic layer FOL may have a thickness in a range of about 2 Å to about 10 μm. When the thickness of the first organic layer FOL is about 2 Å or more, the absorption rate of laser light having a wavelength of about 308 nm may be improved. When the thickness of the first organic layer FOL is about 10 μm or less, the height difference between the first organic layer FOL and the pixel electrode PE1 may be prevented from undesirably increasing, so that the light emitting element LE may be easily adhered onto the pixel electrode in a process to be described later.

The wavelength conversion member 200 may be located on the light emitting element unit LEP. The wavelength conversion member 200 may include a partition wall PW, a wavelength conversion layer QDL, the color filters CF1, CF2, and CF3, the light blocking member BK, and a passivation layer PTL.

The partition wall PW may be located on the common electrode CE of the display area DPA, and may partition the plurality of emission areas EA1, EA2, and EA2 together with the bank BNL. The partition wall PW may extend in the first direction DR1 and the second direction DR2, and may be formed in a lattice shape pattern throughout the display area DA. In addition, the partition wall PW may not overlap the plurality of emission areas EA1, EA2, and EA3, and may overlap the non-emission area NEA.

The partition wall PW may include a plurality of openings OP1, OP2, and OP3 exposing the lower common electrode CE. The plurality of openings OP1, OP2, and OP3 may include a first opening OP1 overlapping the first emission area EA1, a second opening OP2 overlapping the second emission area EA2, and a third opening OP3 overlapping the third emission area EA3. Here, the plurality of openings OP1, OP2, and OP3 may correspond to the plurality of emission areas EA1, EA2, and EA3. That is, the first opening OP1 may correspond to the first emission area EA1, the second opening OP2 may correspond to the second emission area EA2, and the third opening OP3 may correspond to the third emission area EA3.

The partition wall PW may serve to provide a space in which first and second wavelength conversion layers QDL1 and QDL2 may be formed. To this end, the partition wall PW may have a thickness (e.g., predetermined thickness), and, for example, the thickness of the partition wall PW may be in a range of about 1 μm to about 10 μm. The partition wall PW may include an organic insulating material to have a thickness (e.g., predetermined thickness). The organic insulating material may contain, for example, epoxy resin, acrylic resin, cardo resin, and/or imide resin.

The first wavelength conversion layer QDL1 may be located in each of the first openings OP1. The first wavelength conversion layer QDL1 may be formed of an island pattern in a shape of dots spaced apart from each other. The first wavelength conversion layer QDL1 may include a first base resin BRS1 and a first wavelength conversion particle WCP1. The first base resin BRS1 may include a transparent organic material. For example, the first base resin BRS1 may contain epoxy resin, acrylic resin, cardo resin, and/or imide resin. The first wavelength conversion particle WCP1 may be a quantum dot (QD), a quantum rod, a fluorescent material, and/or a phosphorescent material. For example, a quantum dot may be a particulate material that emits light of a corresponding color when an electron transitions from a conduction band to a valence band.

The quantum dot may be a semiconductor nanocrystal material. The quantum dot may have a corresponding band gap according to its composition and size. Thus, the quantum dot may absorb light, and then may emit light having an intrinsic wavelength. Examples of semiconductor nanocrystal of quantum dots may include group IV nanocrystal, group II-VI compound nanocrystal, group III-V compound nanocrystal, group IV-VI nanocrystal, a combination thereof, or the like.

The first wavelength conversion layer QDL1 may be formed in the first opening OP1 of the first emission area EA1. The first wavelength conversion layer QDL1 may emit light by converting or shifting the peak wavelength of incident light to another corresponding peak wavelength. The first wavelength conversion layer QDL1 may convert a portion of the blue light emitted from the light emitting element LE into light similar to red light, which is the first light. The first wavelength conversion layer QDL1 may emit light similar to red light, and thus may perform conversion into red light, which is the first light, through the first color filter CF1.

The second wavelength conversion layer QDL2 may be located in each of the second openings OP2. The second wavelength conversion layer QDL2 may be formed of an island pattern in a shape of dots spaced apart from each other. For example, the second wavelength conversion layer QDL2 may overlap the second emission area EA2. The second wavelength conversion layer QDL2 may include a second base resin BRS2 and a second wavelength conversion particle WCP2. The second base resin BRS2 may contain a transparent organic material. Accordingly, the second wavelength conversion layer QDL2 may emit light by converting or shifting the peak wavelength of incident light to another corresponding peak wavelength. The second wavelength conversion layer QDL2 may convert a portion of the blue light emitted from the light emitting element LE into light similar to green light, which is the second light. The second wavelength conversion layer QDL2 may emit light similar to green light, and thus may perform conversion into red light, which is the first light, through the second color filter CF2.

In the third emission area EA3, and for example, only a transparent organic material may be formed in the third opening OP3 so that the blue light emitted from the light emitting element LE may be emitted through the third color filter CF3 as it is.

The plurality of color filters CF1, CF2, and CF3 may be located on the partition wall PW and the first and second wavelength conversion layers QDL1 and QDL2, as well as the transparent organic material formed in the third opening OP3. The plurality of color filters CF1, CF2, and CF3 may overlap the plurality of openings OP1, OP2, OP3 and the first and second wavelength conversion layers QDL1 and QDL2. The plurality of color filters CF1, CF2, and CF3 may include a first color filter CF1, a second color filter CF2, and a third color filter CF3.

The first color filter CF1 may overlap the first emission area EA1. In addition, the first color filter CF1 may be located on the first opening OP1 of the partition wall PW to overlap the first opening OP1. The first color filter CF1 may transmit the first light emitted from the light emitting element LE, and may absorb or block the second light and the third light. For example, the first color filter CF1 may transmit light of a blue wavelength band, and may absorb or block light of other wavelength bands such as green and red.

The second color filter CF2 may overlap the second emission area EA2. In addition, the second color filter CF2 may be located on the second opening OP2 of the partition wall PW to overlap the second opening OP2. The second color filter CF2 may transmit the second light and may absorb or block the first light and the third light. For example, the second color filter CF2 may transmit light of a green wavelength band and may absorb or block light of other wavelength bands such as blue and red.

The third color filter CF3 may overlap the third emission area EA3. In addition, the third color filter CF3 may be located on the third opening OP3 of the partition wall PW to overlap the third opening OP3. The third color filter CF3 may transmit the third light and may absorb or block the first light and the second light. For example, the third color filter CF3 may transmit light of a red wavelength band and may absorb or block light of other wavelength bands such as blue and green.

A planar area of each of the plurality of color filters CF1, CF2, and CF3 may be larger than a planar area of each of the plurality of emission areas EA1, EA2, and EA3, respectively. For example, the first color filter CF1 may have a larger planar area than the first emission area EA1. The second color filter CF2 may have a larger planar area than the second emission area EA2. The third color filter CF3 may have a larger planar area than the third emission area EA3. However, the present disclosure is not limited thereto, and a planar area of each of the plurality of color filters CF1, CF2, and CF3 may be the same as a planar area of each of the plurality of emission areas EA1, EA2, and EA3 (e.g., respectively).

Referring to FIG. 6, the light blocking member BK may be located on the partition wall PW. The light blocking member BK may overlap the non-emission area NEA to block light transmission in an area corresponding thereto. The light blocking member BK may be located approximately in a lattice shape in plan view, similar to the bank BNL or the partition wall PW. The light blocking member BK may overlap the bank BNL, the first organic layer FOL, and the partition wall PW, and may not overlap the emission areas EA1, EA2, and EA3.

In one or more embodiments, the light blocking member BK may include an organic light blocking material, and may be formed by coating and exposing processes with the organic light blocking material. The light blocking member BK may include a dye or pigment having light blocking properties, and may be a black matrix. At least a part of the light blocking member BK may overlap the adjacent color filters CF1, CF2, and CF3, and the color filters CF1, CF2, and CF3 may be located on at least a part of the light blocking member BK.

The passivation layer PTL may be located on the plurality of color filters CF1, CF2, and CF3 and the light blocking member BK. The first passivation layer PTL may be located on the uppermost portion of the display device 10 to protect the lower plurality of color filters CF1, CF2, and CF3 and the light blocking member BK. One surface, for example, a bottom surface of the passivation layer PTL may be in contact with the top surface of each of the plurality of color filters CF1, CF2, and CF3 and the light blocking member BK.

The passivation layer PTL may include an inorganic insulating material to protect the plurality of color filters CF1, CF2, and CF3 and the light blocking member BK. For example, the first passivation layer PTL may include silicon oxide (SiOx), silicon nitride (SiNx), silicon oxynitride (SiOxNy), aluminum oxide (AlxOy), aluminum nitride (AlN), or the like, but is not limited thereto. The first passivation layer PTL may have a thickness (e.g., predetermined thickness), for example, in a range of about 0.01 μm to about 1 μm. However, the present disclosure is not limited thereto.

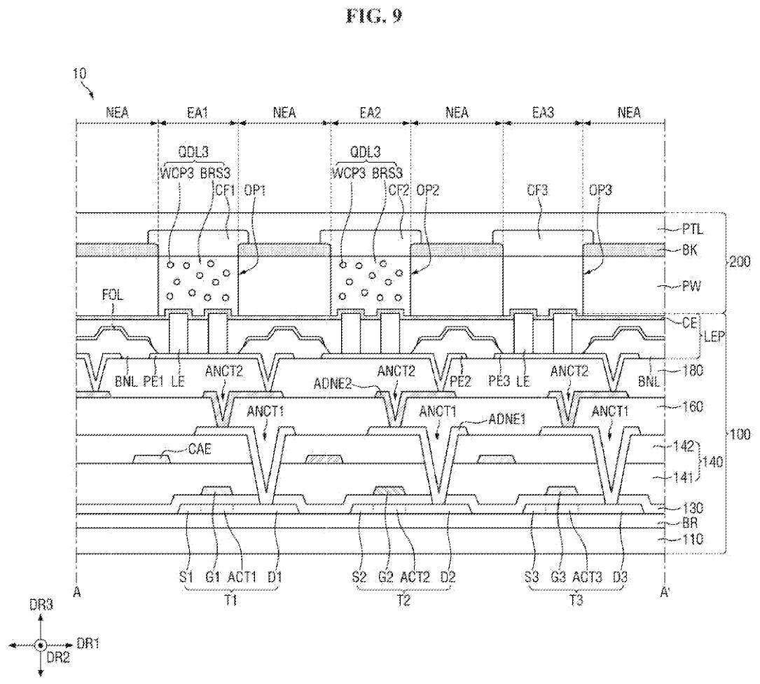

FIG. 9 is a cross-sectional view schematically illustrating a cross section A-A′ of FIG. 2 according to one or more other embodiments.

Referring to FIG. 9, a third wavelength conversion layer QDL3 may be located in each of the first and second openings OP1 and OP2.

The third wavelength conversion layer QDL3 may emit light by converting or shifting the peak wavelength of incident light to another corresponding peak wavelength. The third wavelength conversion layer QDL3 may convert a portion of the first (blue) light emitted from the light emitting element LE into the fourth (yellow) light. In the third wavelength conversion layer QDL3, the first light and the fourth light may be mixed to emit the fifth (white) light. The fifth light is converted into the first light through the first color filter CF1, and is converted into the second light through the second color filter CF2.

The third wavelength conversion layer QDL3 may be located in each of the first and second openings OP1 and OP2, and parts thereof may be spaced apart from other respective parts thereof. That is, the third wavelength conversion layer QDL3 may be formed of an island pattern in a shape of dots spaced apart from each other. For example, the third wavelength conversion layer QDL3 may be located only in each of the first opening OP1 and the second opening OP2, in a one-to-one correspondence. In addition, the third wavelength conversion layer QDL3 may overlap each of the first emission area EA1 and the second emission area EA2. In one or more embodiments, each of the third wavelength conversion layers QDL3 may completely overlap the first emission area EA1 and the second emission area EA2.

The third wavelength conversion layer QDL3 may include a third base resin BRS3 and third wavelength conversion particles WCP3. The third base resin BRS3 may contain a transparent organic material. For example, the third base resin BRS3 may contain epoxy resin, acrylic resin, cardo resin, and/or imide resin.

The third wavelength conversion particle WCP3 may convert the first light incident from the light emitting element LE into the fourth light. For example, the third wavelength conversion particle WCP3 may convert light of a blue wavelength band into light of a yellow wavelength band. The third wavelength conversion particle WCP3 may be a quantum dot (QD), a quantum rod, a fluorescent material, or a phosphorescent material. For example, a quantum dot may be a particulate material that emits light of a corresponding color when an electron transitions from a conduction band to a valence band.

As the thickness of the third wavelength conversion layer QDL3 increases in the third direction DR3, the content of the third wavelength conversion particles WCP3 included in the wavelength conversion layer QDL increases, so that the light conversion efficiency of the third wavelength conversion layer QDL3 may increase. Accordingly, the thickness of the third wavelength conversion layer QDL3 may be set in consideration of the light conversion efficiency of the third wavelength conversion layer QDL3.

In the above-described third wavelength conversion layer QDL3, a portion of the first light emitted from the light emitting element LE may be converted into fourth light in the third wavelength conversion layer QDL3. The third wavelength conversion layer QDL3 may emit fifth (white) light by mixing the first light and the fourth light. For the fifth light emitted from the third wavelength conversion layer QDL3, the first color filter CF1 to be described later may transmit only the first light, and the second color filter CF2 may transmit only the second light. Accordingly, the light emitted from the wavelength conversion member 200 may be the red and green light of the first light and the second light. In the third emission area EA3, only a transparent organic material may be formed in the third opening OP3 so that the blue light emitted from the light emitting element LE may be emitted through the third color filter CF3 as it is. Accordingly, full colors may be produced.

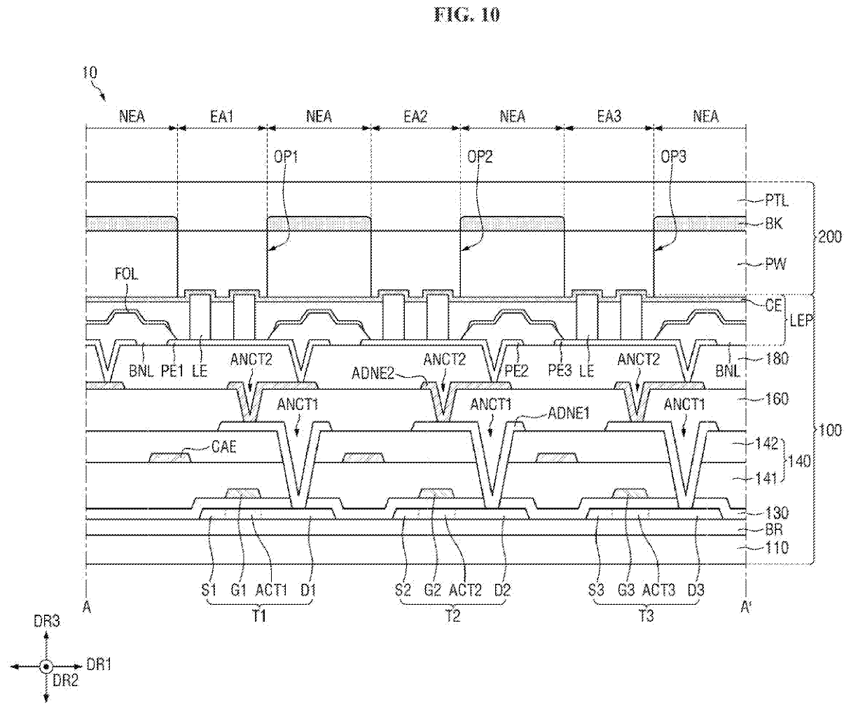

FIG. 10 is a cross-sectional view schematically illustrating a cross section A-A′ of FIG. 2 according to one or more other embodiments.

As described above, the color of the light emitted from the active layer MQW of each light emitting element LE may vary according to the content of indium (In). As the content of indium (In) decreases, the wavelength band of the light emitted by the active layer may move to the red wavelength band, and as the content of indium (In) increases, the wavelength band of the light emitted by the active layer may move to the blue wavelength band. Accordingly, when the content of indium (In) in the active layer MQW of each light emitting element LE formed in the first emission area EA1 is about 15% or less, a first light in a red wavelength band with the main peak wavelength in a range of about 600 nm to about 750 nm may be emitted.

When the content of indium (In) in the active layer MQW of each light emitting element LE formed in the second emission area EA2 is about 25%, a second light in a green wavelength band with the main peak wavelength in a range of about 480 nm to about 560 nm may be emitted.

When the content of indium (In) in the active layer MQW of each light emitting element LE formed in the third emission area EA3 is about 35% or more, the active layer MQW may emit a third light in a blue wavelength band with the main peak wavelength in a range of about 370 nm to about 460 nm.

Each light emitting element LE formed in the first emission area EA1 may emit a first light of a red wavelength band, each light emitting element LE formed in the second emission area EA2 may emit a second light of a green wavelength band, and each light emitting element LE formed in the third emission area EA3 may emit a third light of a blue wavelength band. In this case, the color filters CF1, CF2, and CF3 may be omitted.

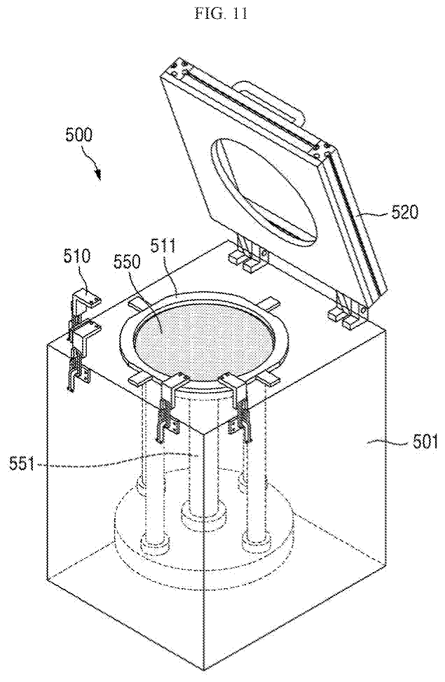

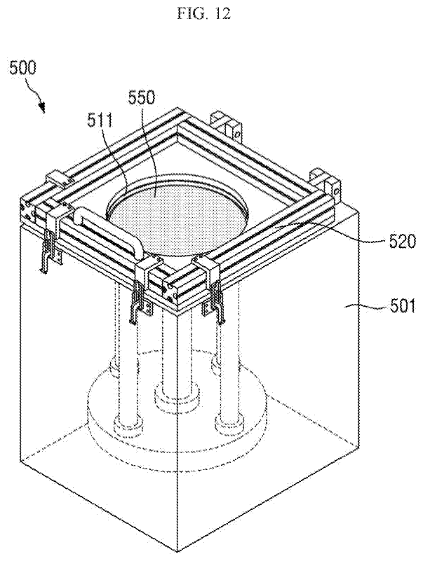

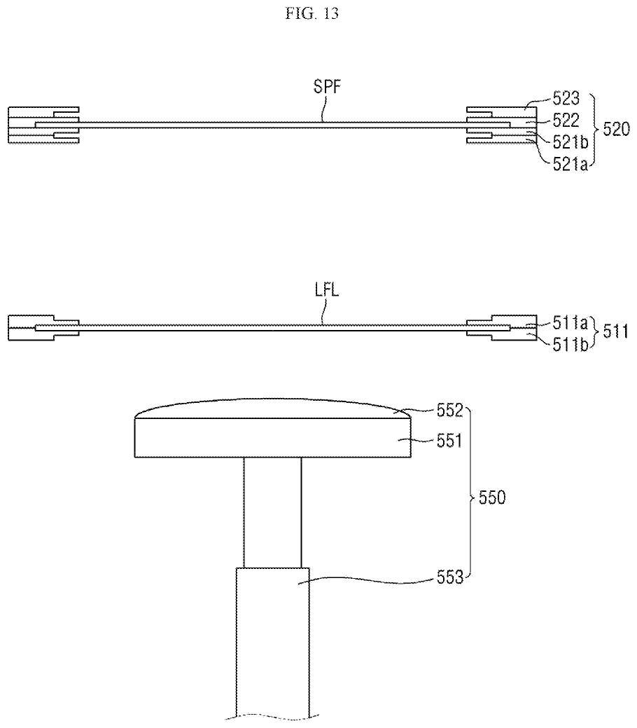

FIG. 11 is a perspective view schematically illustrating an apparatus for fabricating a display panel according to one or more embodiments. FIG. 12 is another perspective view illustrating the fabricating apparatus illustrated in FIG. 11 in another form. FIG. 13 is a cross-sectional view illustrating a film mounting member, a stretching processing member, and a transfer processing member illustrated in FIGS. 11 and 12.

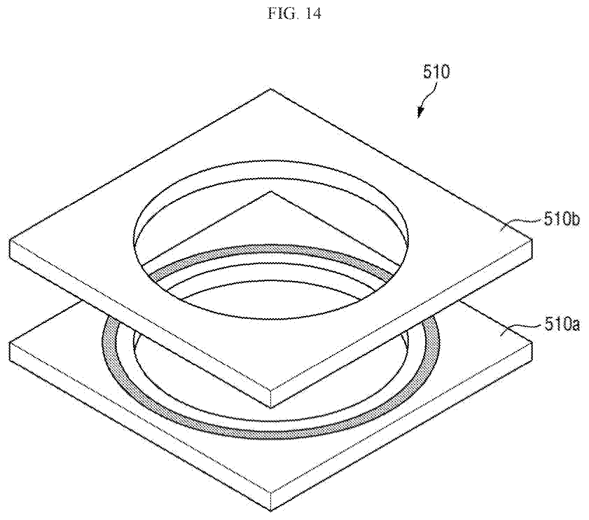

Referring to FIGS. 11 to 13, an apparatus for fabricating a display panel includes a housing 501, a fixing frame 511, a film mounting member 510 (see FIG. 14), a stretching processing member 550, a transfer processing member 520, and in some embodiments, a mask frame, and a pressing frame.

For example, the fixing frame 511 fixes the outer perimeter of a transfer film LFL on which the plurality of light emitting elements LE are arranged. The fixing frame 511 includes a pair of first and second assembly frames 511a and 511b in which a circular opening is formed. Here, the first and second assembly frames 511a and 511b are formed in the form of a circular or polygonal (e.g., quadrilateral) panel or frame in which a circular opening is formed. The first and second assembly frames 511a and 511b may be formed in the form of a circular ring or a ring-type frame.

The first and second assembly frames 511a and 511b are assembled to face each other. In addition, the first and second assembly frames 511a and 511b may be assembled in such a way that the first assembly frame 511a is fitted into another second assembly frame 511b. The first and second assembly frames 511a and 511b press in a circular shape and fix (e.g., secure or hold) the outer perimeter of the transfer film LFL, excluding the opening area, by the circular opening and the peripheral frame/peripheral frame structure of the opening. The opening structure of the first and second assembly frames 511a and 511b may be formed in a polygonal shape such as an elliptical shape or a quadrilateral shape depending on the stretching direction of the transfer film LFL, but to increase uniformity of the stretching direction of the transfer film LFL, it is suitable to apply the circular opening to press in a circular shape and fix the outer perimeter of the transfer film LFL.

The film mounting member 510 is mounted on or inside the housing 501 constituting the outer shape or frame of the fabricating apparatus. The film mounting member 510 includes a seating portion on which the fixing frame 511 is seated, and at least one clip or annular fastening member that presses and fixes the outer surface of the fixing frame 511. The film mounting member 510 fixes the fixing frame 511 by fastening at least one outer perimeter of the fixing frame 511 seated on the front surface seating portion with at least one clip or an annular fastening member.

FIG. 14 is an exploded perspective view illustrating another form of the film mounting member illustrated in FIG. 13.

Referring to FIG. 14, the film mounting member 510 includes a first mounting frame 510a on which the fixing frame 511 is seated, and a second mounting frame 510b that presses and fixes a portion of the front surface and the outer perimeter of the fixing frame 511 seated on the first mounting frame 510a.

The first mounting frame 510a is formed in the form of a circular or polygonal (e.g., quadrilateral) panel or frame in which a circular opening is formed, and is mounted on the upper or inner side of the housing 501. In addition, the second mounting frame 510b may be formed in the form of a circular or polygonal (e.g., quadrilateral) panel or frame in which a circular opening is formed and may be assembled to face the first mounting frame 510a. That is, the first and second mounting frames 510a and 510b may be assembled to face each other and overlap each other, and thus may fix the fixing frame 511 by pressing, in a circular shape, the outer perimeter and a portion of the front and rear surfaces of the fixing frame 511 not including the circular opening area.

Referring to FIGS. 11 and 13, the stretching processing member 550 presses the transfer film LFL fixed by the film mounting member 510 and the fixing frame 511 (e.g., the transfer film LFL on which the light emitting elements LE are arranged) in any respective direction to stretch the entire width of the transfer film LFL in the outer perimeter direction (e.g., outwardly). For example, the stretching processing member 550 may stretch the entire width of the transfer film LFL in the outer perimeter direction by pressing the rear surface of the transfer film LFL on which the light emitting elements LE are arranged on the front surface in the front direction.

The stretching processing member 550 includes a plate-shaped frame 551, an elastic press 552, and a transfer driving member 553.

The plate-shaped frame 551 may be formed in a panel type of a disk shape or polygonal shape.

The elastic press 552 is formed in a convex shape so that the front surface has a curvature (e.g., a preset curvature), and so that the rear surface is formed in a flat plate shape. The elastic press 552 is attached or assembled to the front surface of the plate-shaped frame 551 by having the rear surface thereof in a flat plate shape that is located on the front surface of the plate-shaped frame 551. The convex curvature of the elastic press 552 may be set and applied differently according to suitability of at least one of the size or diameter of the transfer film LFL on which the plurality of light emitting elements LE are arranged, the arrangement width or arrangement interval of the plurality of light emitting elements LE, or the stretching width of the transfer film LFL. The elastic press 552 is formed of an elastic material such as plastic, chromoly, a metal layer, silicon, carbon, or rubber.

Because the front surface of the elastic press 552 is formed to have a curvature, the transfer film LFL may be stretched while maintaining the curvature during the stretching process due to the curved shape of the front surface of the elastic press 552. Accordingly, the stretching width and direction of the transfer film LFL may be stretched more evenly, and air bubble generation between the transfer film LFL and the support film SPF, which is compressed on the front surface of the transfer film LFL or another transfer film, may be reduced or prevented.

The transfer driving member 553 supports the rear surface of the plate-shaped frame 551 and moves the plate-shaped frame 551 in the front/forward direction or the rear/reverse direction of the plate-shaped frame 551, so that the rear surface of the transfer film LFL is pressed in the front/forward direction by the elastic press 552 located on the front surface of the plate-shaped frame 551. The transfer driving member 553 may be formed of a hydraulic pumping type, such as a piston, and one side may be assembled to the rear surface of the plate-shaped frame 551 and the other side may be assembled with a pneumatic or hydraulic pressure regulator. Accordingly, the transfer driving member 553 may move the plate-shaped frame 551 in a direction facing the transfer processing member 520 or in the opposite direction by a pneumatic or hydraulic pressure regulator.

The transfer processing member 520 may be located and assembled with one side thereof assembled to any one side surface of the upper portion of the housing 501 to open and close the upper portion of the housing 501 and the fixing frame 511 in one side direction of the upper portion of the housing 501. In addition, the transfer processing member 520 may be installed in a cap form in the upper direction of the housing 501 at a preset interval between the upper portion of the housing 501 and the fixing frame 511, and in this case, may be installed to move either in a direction closer to or in a direction away from the upper portion of the housing 501 and the fixing frame 511.

The transfer processing member 520 moves in the direction of the transfer film LFL stretched in its entire width by the stretching processing member 550 in a state in which the support film SPF or another transfer film is mounted, and thus adheres the plurality of light emitting elements LE having a varied arrangement width by the stretched transfer film LFL to the support film SPF or to another transfer film. In addition, in the process of detachment in the opposite direction with respect to the transfer film LFL, the plurality of light emitting elements LE having a varied arrangement width transfer to the support film SPF or another transfer film.

The transfer processing member 520 includes first and second frame binding units 521a and 521b, a film binding unit 522, and a frame fixing unit 523.

The first and second frame binding units 521a and 521b press the outer perimeter of the mask frame and partial areas of the front and rear surfaces to fix (e.g., secure) the outer perimeter of the mask frame.

The first and second frame binding units 521a and 521b may be formed in a frame form formed with a circular opening, and may be attached to each other to face each other, so that the outer perimeter of the mask frame may be fixed in a circular shape. Here, the first and second frame binding units 521a and 521b may be formed in a frame form of a circle shape in which a circular opening is formed, or a polygonal shape such as a quadrilateral shape. In addition, the first and second frame binding units 521a and 521b may be formed in a frame form of a ring type.

In addition to the method in which the first and second frame binding units 521a and 521b are assembled to face each other, the first frame binding unit 521a may be assembled by being fitted into the different second frame binding unit 521b. Accordingly, the first and second frame binding units 521a and 521b may fix the outer perimeter of the mask frame by pressing in a circular shape the outer perimeter of the mask frame, excluding the circular opening area, by the circular opening. The openings of the first and second frame binding units 521a and 521b may be applied in a polygonal shape, such as a quadrilateral shape or an elliptical shape, but may be formed in a circular shape to correspond to the stretched shape and fixed shape of the transfer film LFL.

The film binding unit 522 is positioned on the rear surfaces of the first and second frame binding units 521a and 521b, is piled to overlap any one frame binding unit (e.g., frame binding unit 521b) of the first and second frame binding units 521a and 521b, and is bound and assembled with any one of the overlapping frame binding units (e.g., frame binding unit 521b). The film binding unit 522 presses the outer perimeter and partial areas of the front and rear surfaces of the support film SPF or another transfer film according to the binding structure to be bound with the overlapping frame binding unit 521b, and fixes the outer perimeter of the support film or another transfer film in a circular shape. For example, the film binding unit 522 may be formed in the form of a circular or polygonal (e.g., quadrilateral) panel or frame in which a circular opening is formed. The film binding unit 522 fixes the outer perimeter of the support film SPF in a circular shape by pressing the outer perimeter and a portion of the front and rear surfaces of the support film SPF, excluding the circular opening area, by the circular opening. When another transfer film is mounted on the film binding unit 522, the outer perimeter of the transfer film is fixed by pressing in a circular shape the outer perimeter of the corresponding transfer film, except for the circular opening area, by the circular opening.

The frame fixing unit 523 is positioned on the rear surface of the film binding unit 522, is piled to overlap the film binding unit 522, and is bound and assembled to the rear surface of the film binding unit 522. The frame fixing unit 523 fixes the outer perimeter of the pressing frame in a circular shape by pressing the outer perimeter and partial areas of the front and rear surfaces of the pressing frame according to the binding structure with the overlapping film binding unit 522.

The film binding unit 522 may be formed in the form of a circular or polygonal panel or frame in which a circular or quadrilateral opening is formed. The film binding unit 522 fixes the outer perimeter of the pressing frame by pressing the outer perimeter and a portion of the front and rear surfaces of the pressing frame, except for the circular or quadrangular opening area, by the circular or quadrangular opening.

As illustrated in FIG. 13, the first and second frame binding units 521a and 521b, the film binding unit 522, and the frame fixing unit 523 of the transfer processing member 520 are piled and assembled by being sequentially overlapped with each other, so that all may be moved at the same speed and direction.

Hereinafter, a fabricating process of a display panel according to one or more embodiments will be described with reference to other drawings.

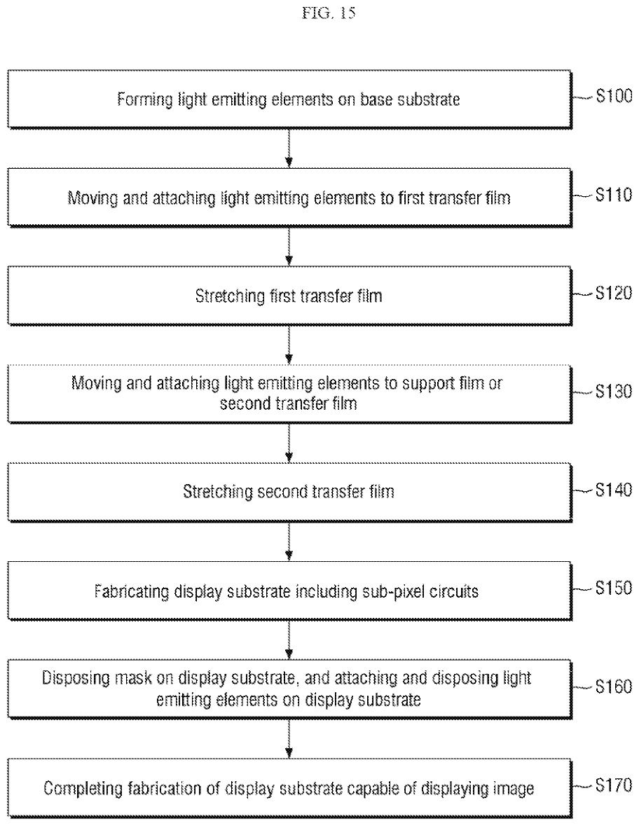

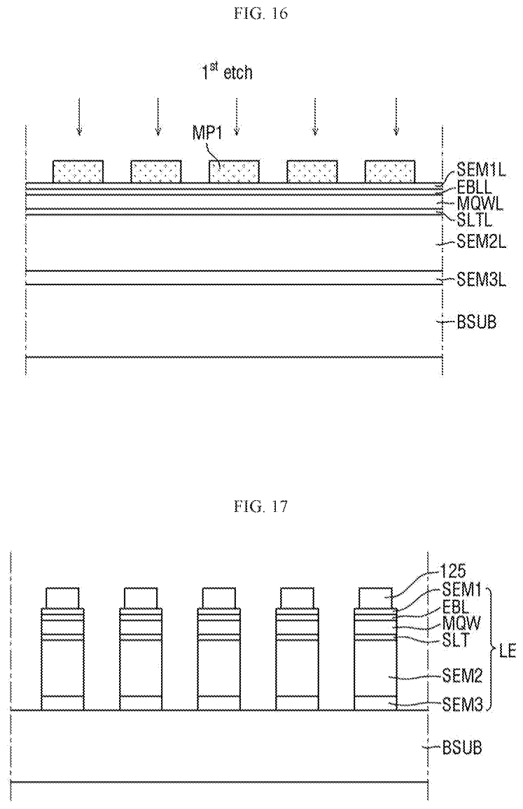

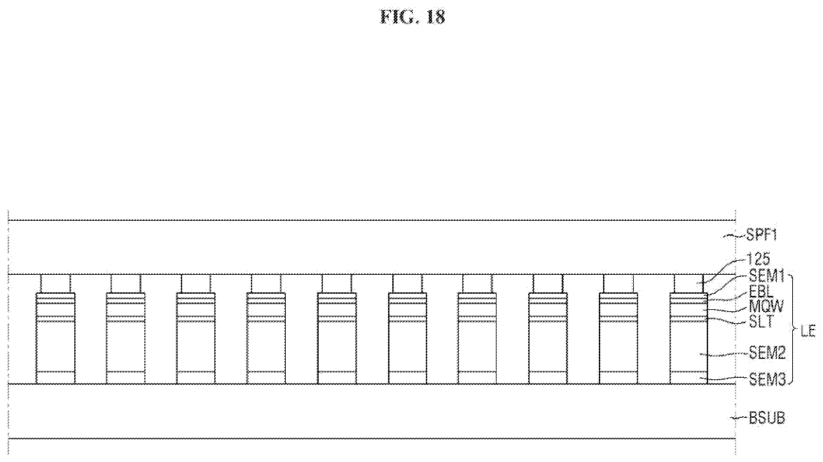

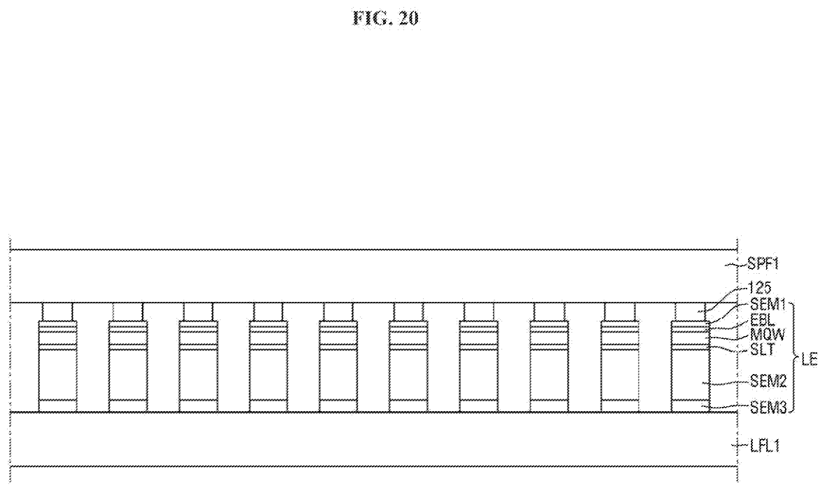

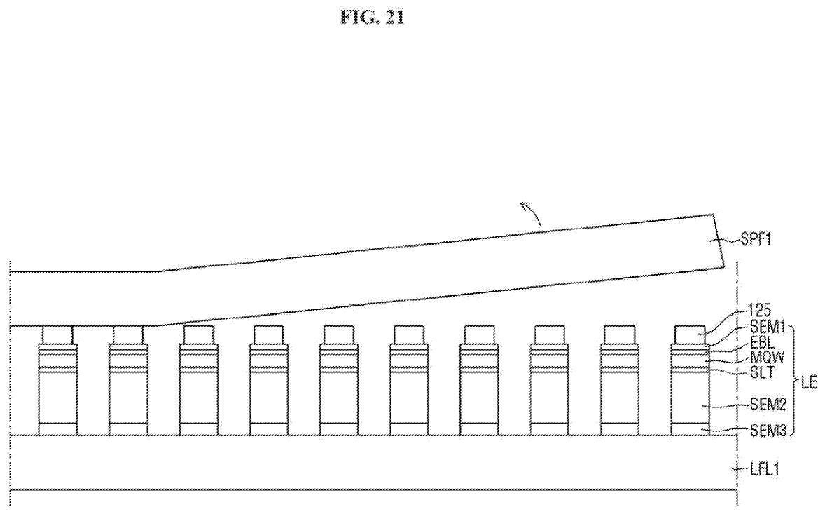

FIG. 15 is a flowchart illustrating a fabricating method of a display panel using the fabricating apparatus of FIGS. 11 and 12. In addition, FIGS. 16 to 21 are cross-sectional views for explaining a fabricating method of a light emitting element according to one or more embodiments.

First, referring to FIGS. 15 and 16, the light emitting elements LE may be separately formed on a base substrate BSUB (operation S100 of FIG. 15). In this case, a sapphire substrate (Al₂O₃) or a silicon wafer including silicon or the like is prepared as the base substrate BSUB. A plurality of semiconductor material layers SEM3L, SEM2L, SLTL, MQWL, EBLL, and SEM1L are formed on the base substrate BSUB. The plurality of semiconductor material layers grown by an epitaxial method may be formed by growing seed crystals. Here, the semiconductor material layer may be formed using one of electron beam deposition, physical vapor deposition (PVD), chemical vapor deposition (CVD), plasma laser deposition (PLD), dual-type thermal evaporation, sputtering, and metal organic chemical vapor deposition (MOCVD). However, the present disclosure is not limited thereto.

Generally, a precursor material for forming the plurality of semiconductor material layers may be selected to form a target material in a typically selectable range without any limitation. For example, the precursor material may be a metal precursor including an alkyl group such as a methyl group or an ethyl group. Examples of the precursor material may include, but are not limited to, trimethylgallium Ga(CH₃)₃, trimethylaluminum Al(CH₃)₃, and triethyl phosphate (C₂H₅)₃PO₄.

For example, the third semiconductor material layer SEM3L is formed on the base substrate BSUB. Although it is shown in the drawing that one third semiconductor layer SEM3 is deposited, the present disclosure is not limited thereto, and a plurality of layers may be formed. The third semiconductor material layer SEM3L may reduce a lattice constant difference between the second semiconductor material layer SEM2L and the base substrate BSUB. As one example, the third semiconductor material layer SEM3L may include an undoped semiconductor, and may be a material not doped with an n-type or p-type. In one or more embodiments, the third semiconductor material layer SEM3L may be, but is not limited to, at least one of undoped InAlGaN, GaN, AlGaN, InGaN, AlN, or InN.

The second semiconductor material layer SEM2L, the superlattice material layer SLTL, the active material layer MQWL, the electron blocking material layer EBLL, and the first semiconductor material layer SEM1L are sequentially formed on the third semiconductor material layer SEM3L using the above-described method. Next, the plurality of semiconductor material layers SEM3L, SEM2L, SLTL, MQWL, EBLL, and SEM1L are etched to form the plurality of light emitting elements LE.

For example, a plurality of first mask patterns MP1 are formed on the first semiconductor material layer SEM1L. The first mask pattern MP1 may be a hard mask including an inorganic material or a photoresist mask including an organic material. The first mask pattern MP1 prevents or protects the plurality of semiconductor material layers SEM3L, SEM2L, SLTL, MQWL, EBLL, and SEM1L located therebelow from being etched. Then, the plurality of light emitting elements LE are formed by partially etching (1st etch) the plurality of semiconductor material layers using the plurality of first mask patterns MP1 as a mask.

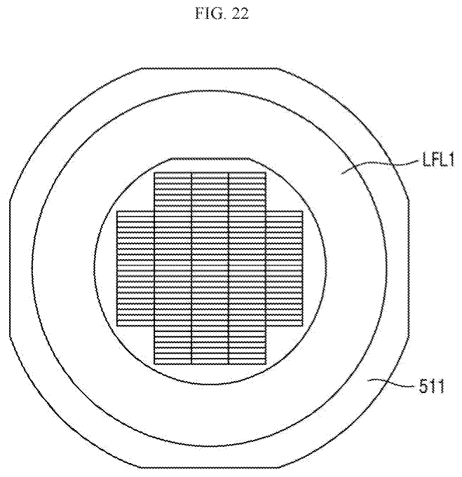

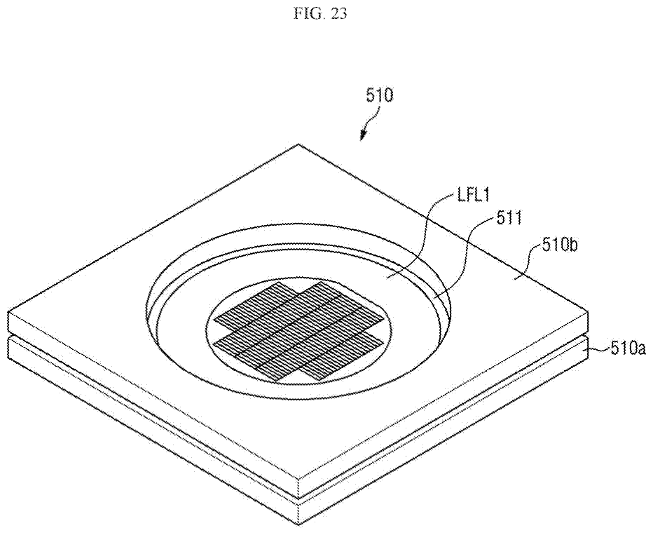

As illustrated in FIG. 22, the plurality of semiconductor material layers SEM3L, SEM2L, SLTL, MQWL, EBLL, and SEM1L that do not overlap the first mask pattern MP1 are etched and removed on the base substrate BSUB, and a portion that is not etched due to overlapping with the first mask pattern MP1 may be formed to be the plurality of light emitting elements LE.

The semiconductor material layers may be etched by a conventional method. For example, the process of etching the semiconductor material layers may be performed by a dry etching method, a wet etching method, a reactive ion etching (RIE) method, a deep reactive ion etching (DRIE) method, an inductively coupled plasma reactive ion etching (ICP-RIE) method, or the like. The dry etching method may be suitable for vertical etching because anisotropic etching can be performed. In the case of using the aforementioned etching technique, it may be possible to use Cl₂ or O₂ as an etchant. However, the present disclosure is not limited thereto.

The plurality of semiconductor material layers SEM3L, SEM2L, SLTL, MQWL, EBLL, and SEM1L overlapping the first mask pattern MP1 are not etched and are formed as the plurality of light emitting elements LE. Accordingly, the plurality of light emitting elements LE are formed to include the third semiconductor layer SEM3, the second semiconductor layer SEM2, the superlattice layer SLT, the active layer MQW, the electron blocking layer EBL, and the first semiconductor layer SEM1.

Next, the connection electrodes 125 are respectively formed on the plurality of light emitting elements LE by stacking a connection electrode material layer on the base substrate BSUB and etching the same. The connection electrodes 125 may be formed directly on the top surface of the first semiconductor layer SEM1 of the light emitting element LE. The connection electrode 125 may include a transparent conductive material. For example, the connection electrode 125 may be formed of a transparent conductive oxide (TCO) such as indium tin oxide (ITO) or indium zinc oxide (IZO). In addition, a metal layer having a high reflectivity, such as aluminum (Au), copper (Cu), gold (Au), or the like, may be additionally formed on the connection electrode 125 formed of a transparent conductive oxide.

Referring to FIGS. 23 to 26, to vary the arrangement width of the plurality of light emitting elements LE formed on the base substrate BSUB, that is, the arrangement interval between the plurality of light emitting elements LE, after attaching the top surfaces of the plurality of light emitting elements LE to a first support film SPF1 and moving the same, a process of attaching the bottom surfaces of the plurality of light emitting elements LE to a first transfer film LFL1 and moving the same, may be performed (operation S110 of FIG. 15).

To this end, the first support film SPF1 is first attached on the plurality of light emitting elements LE formed on the base substrate BSUB. Accordingly, each connection electrode 125 of the plurality of light emitting elements LE may be attached to the first support film SPF1. The plurality of light emitting elements LE are located in large numbers, and thus may be attached to the first support film SPF1 without being detached.

The first support film SPF1 may be constituted with a support layer and an adhesive layer located on the support layer. The support layer may be made of a material that is transparent and that has mechanical stability to allow light to pass therethrough. For example, the support layer may include a transparent polymer such as polyester, polyacrylic, polyepoxy, polyethylene, polystyrene, polyethylene terephthalate, or the like. The adhesive layer may include an adhesive material for the adhesion of the light emitting element LE. For example, the adhesive material may include urethane acrylates, epoxy acrylates, polyester acrylates, or the like. The adhesive material may be a material whose adhesive strength changes as ultraviolet (UV) or heat is applied, and thus the adhesive layer may be easily separated from the light emitting element LE.

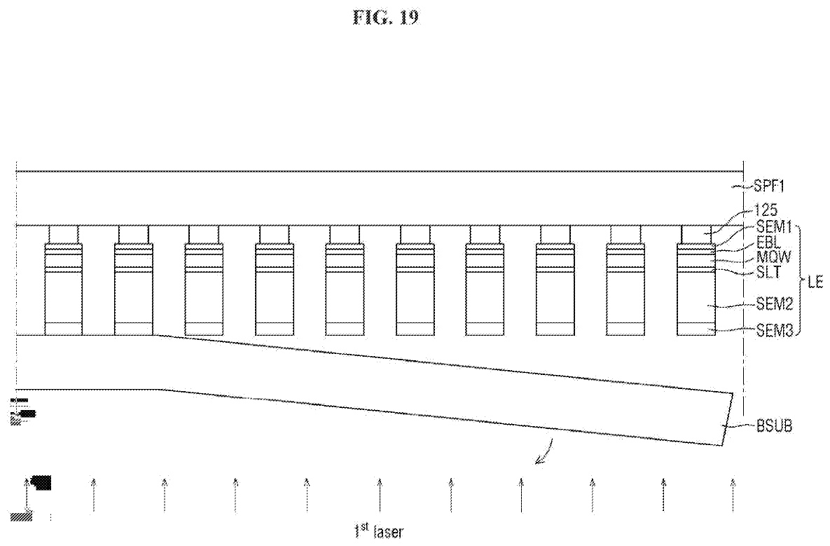

Then, referring to FIG. 19, the base substrate BSUB is separated by irradiating the base substrate BSUB with a laser (1st laser). The base substrate BSUB is separated from each of the third semiconductor layers SEM3 of the plurality of light emitting elements LE.

Referring to FIG. 21, the first transfer film LFL1 is attached to the plurality of light emitting elements LE from which the base substrate BSUB is separated. The first transfer film LFL1 is attached on each of the third semiconductor layers SEM3 of the plurality of light emitting elements LE. The first transfer film LFL1 may be aligned on the plurality of light emitting elements LE, and may be attached to each of the third semiconductor layers SEM3 of the plurality of light emitting elements LE.

The first transfer film LFL1 may include a stretchable material. The stretchable material may include, for example, polyolefine, polyvinyl chloride (PVC), elastomeric silicone, elastomeric polyurethane, elastomeric polyisoprene, or the like. Like the above-described first support film SPF1, the first transfer film LFL1 may also include a support layer and an adhesive layer to adhere and support the plurality of light emitting elements LE.

Referring to FIG. 21, the first support film SPF1 is separated from the plurality of light emitting elements LE. After UV or heat is applied to the first support film SPF1 to reduce the adhesive strength of the adhesive layer of the first support film SPF1, the first support film SPF1 may be physically or naturally separated.

FIG. 22 is a plan view schematically illustrating a first transfer film on which light emitting elements fabricated are arranged according to one or more embodiments. In addition, FIG. 23 is a perspective view schematically illustrating a form in which the first transfer film illustrated in FIG. 22 is mounted on a film mounting member.

Referring to FIG. 22, the first transfer film LFL1 in which the plurality of light emitting elements LE are spaced apart from each other by a first interval (e.g., a predetermined first interval) and located in a dot shape is located in the fixing frame 511, that is between the first and second assembly frames 511a and 511b assembled to face each other. Accordingly, the first and second assembly frames 511a and 511b fix the outer perimeter of the first transfer film LFL1 by pressing in a circular shape the outer perimeter and a portion of the front and rear surfaces of the first transfer film LFL1, except for the circular opening area, by the circular opening.

Referring to FIG. 23, the fixing frame 511 that fixes the outer perimeter of the first transfer film LFL1 is seated on a seating portion of the first mounting frame 510a in which a circular opening is formed. Then, the second mounting frame 510b in which a circular opening is formed is assembled onto the first mounting frame 510a to face the first mounting frame 510a with the fixing frame 511 interposed therebetween. That is, the first and second mounting frames 510a and 510b are assembled to face each other and overlap each other with the fixing frame 511 interposed therebetween, and thus fix the fixing frame 511 by pressing, in a circular shape, the outer perimeter and a portion of the front and rear surfaces of the fixing frame 511 not including the circular opening area.

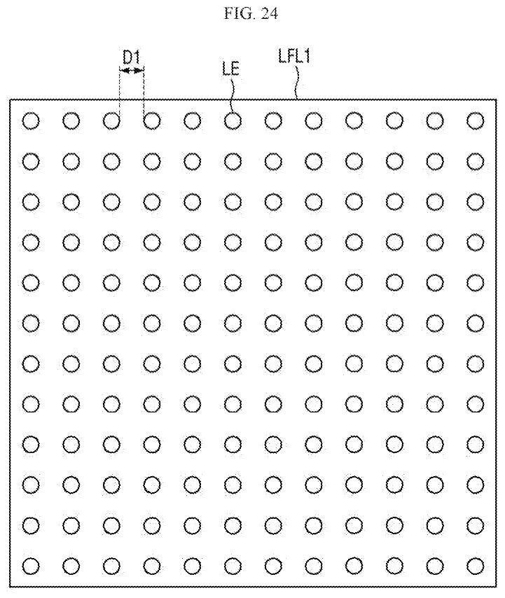

FIG. 24 is a front view (e.g., plan view) schematically partially illustrating an arrangement shape of light emitting elements arranged on the first transfer film illustrated in FIG. 22.

FIG. 24, on the first transfer film LFL1 fixedly located by the fixing frame 511 and the film mounting member 510, the plurality of light emitting elements LE are spaced apart by a first interval D1 to be located in a dot shape.

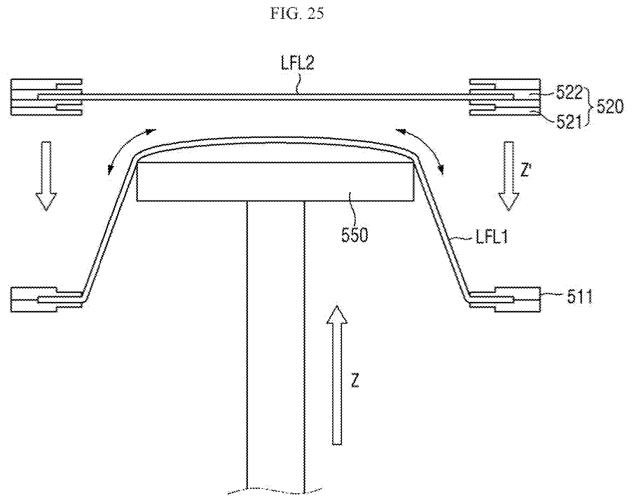

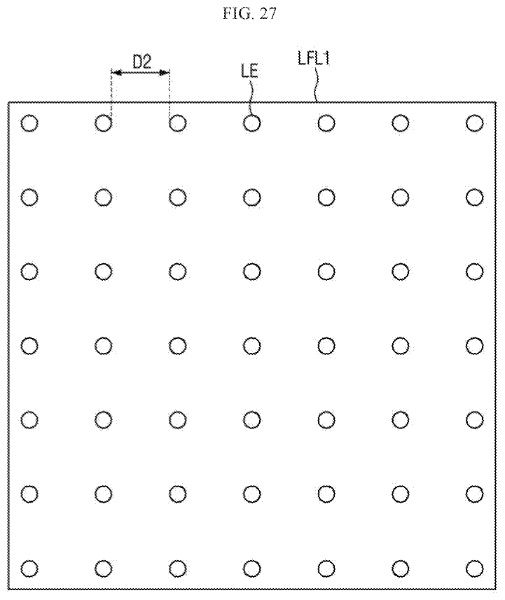

FIGS. 25 to 29 are cross-sectional views and front views for explaining the stretching method of the first transfer film.

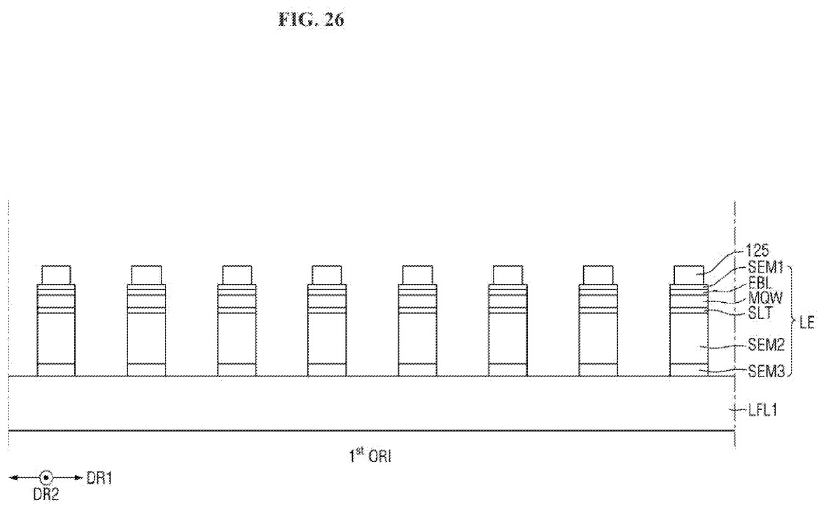

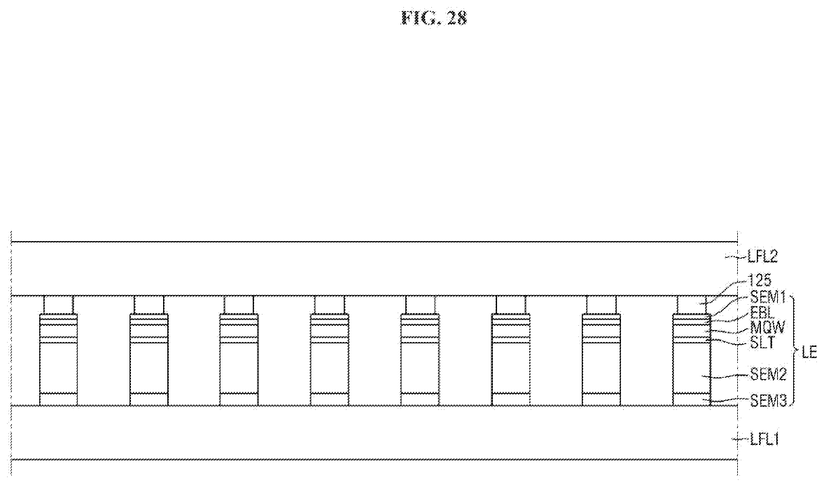

Referring to FIG. 25, as the stretching processing member 550 moves in the rear/backward direction of the first transfer film LFL1 (i.e., the Z-axis arrow direction), the rear surface of the first transfer film LFL1 is pressed in the front direction of the first transfer film LFL1 (operation S120 in FIG. 15). Accordingly, as illustrated in FIGS. 26 and 28, the first transfer film LFL1 is stretched (1st ORI) by the movement of the stretching processing member 550 and the rear surface pressure. The first transfer film LFL1 may be stretched two-dimensionally in the first direction DR1 and the second direction DR2.

As the first transfer film LFL1 is stretched, the plurality of light emitting elements LE adhered on the first transfer film LFL1 may be spaced apart from each other by a second interval D2. That is, the plurality of light emitting elements LE may be substantially uniformly spaced apart from each other by a width of the second interval D2 that is greater than the first interval D1 described above.

The stretching strength (or tensile strength) of the first transfer film LFL1 may be adjusted according to the desired second interval D2 of the light emitting elements LE, and may be, for example, about 120 gf/inch. However, without being limited thereto, the stretching strength/tensile strength may be adjusted according to the second interval D2.

The stretching processing member 550 presses the rear surface of the first transfer film LFL1 in the front direction, and the transfer processing member 520 moves toward the front surface of the first transfer film LFL1 stretched with a second transfer film LFL2 mounted thereon, so that the plurality of light emitting elements LE with varied arrangement widths and the second transfer film LFL2 are attached (operation S130 of FIG. 15). The second transfer film LFL2 may include a support layer and an adhesive layer in the same manner as the above-described first transfer film LFL1.

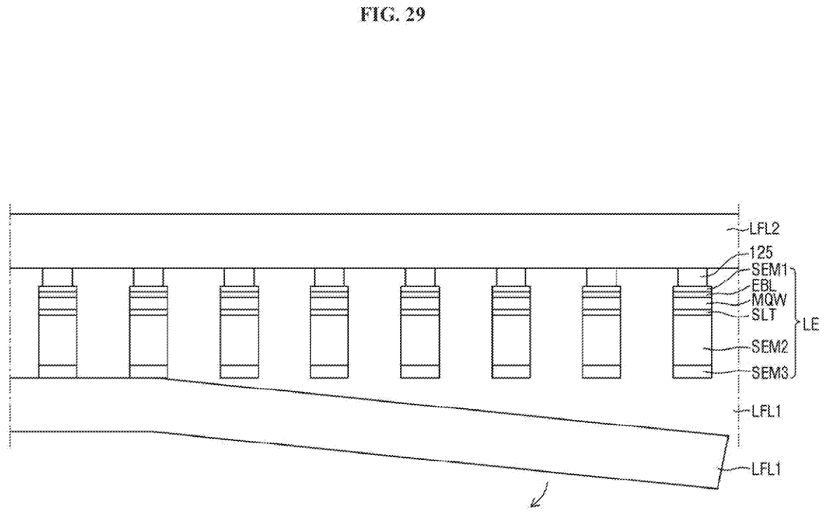

Then, as illustrated in FIG. 29, after UV or heat is applied to the first transfer film LFL1 to reduce the adhesive strength of the adhesive layer of the first transfer film LFL1, the first transfer film LFL1 may be physically or naturally separated from the plurality of light emitting elements LE.

Thereafter, a second transfer film LFL2 in which the plurality of light emitting elements LE are spaced apart from each other by the second interval D2 may be bonded to the display substrate 100 formed up to the pixel electrodes PE1, PE2, and PE3, so that the plurality of light emitting elements LE may be adhered to the display substrate 100 and a display panel may be fabricated. Prior to the process of adhering the plurality of light emitting elements LE on the display substrate 100, at least one of the second transfer film LFL2 and the display substrate 100 may be cut to fit the size or area of the product and then be adhered.

On the other hand, according to the area of the pixel electrodes PE1, PE2, and PE3 and the area and size of the display substrate 100 formed up to the pixel electrodes PE1, PE2, and PE3, it is also suitable to further widen and form the interval between the plurality of light emitting elements LE. Accordingly, a process of additionally stretching the second transfer film LFL2 will be described as follows.

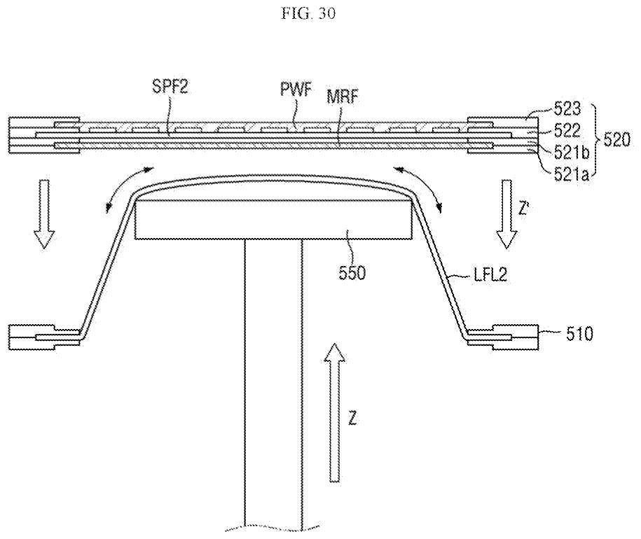

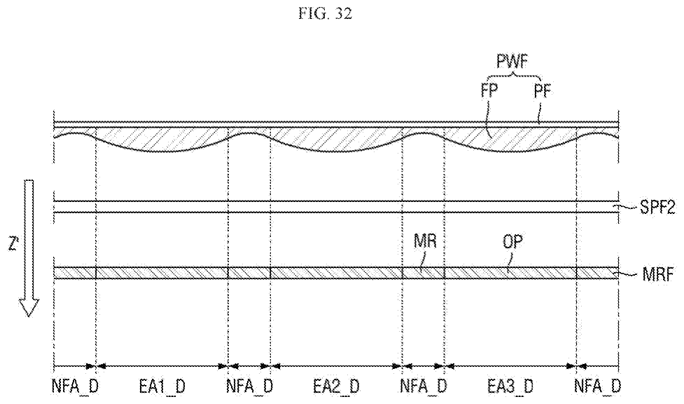

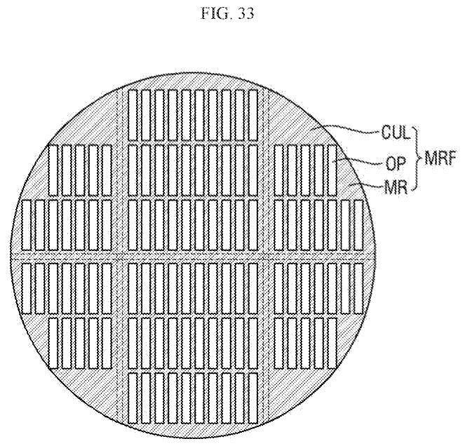

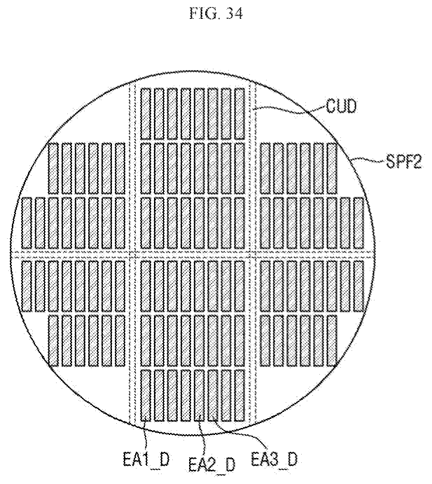

FIGS. 30 to 38 are various views for explaining the stretching method of the second transfer film.

First, referring to FIGS. 25 to 27, when the outer perimeter of the second transfer film LFL2 in which the plurality of light emitting elements LE are located at the second interval D2 is fixed (e.g., secured or held) by the fixing frame 511, the fixing frame 511 fixing the outer perimeter of the second transfer film LFL2 is again fixed with the film mounting member 510. Accordingly, the second transfer film LFL2 fixed by the fixing frame 511 and the film mounting member 510 is located on the front surface of the stretching processing member 550.

The first and second frame binding units 521a and 521b, which are positioned on the lowest surface of the transfer processing member 520, press the outer perimeter of a mask frame MRF to fix the outer perimeter of the mask frame MRF. The mask frame MRF corresponds to the second transfer film LFL2 fixed by the fixing frame 511 and the film mounting member 510, and faces the second transfer film LFL2.

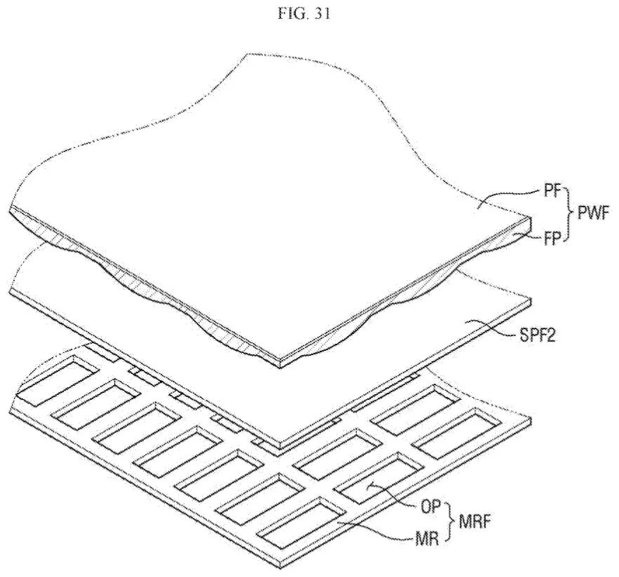

Referring to FIGS. 31 to 34, the mask frame MRF includes a cutting line portion CUL corresponding to a cutting cover area CUD of the second support film SPF2 corresponding to the cutting area of the display panel, and for covering such that the light emitting elements LE are not attached to the cutting cover area CUD of the second support film SPF2. The light emitting elements LE may remain detached from the cutting cover area CUD of the second support film SPF2 due to the cutting line portion CUL of the mask frame MRF. Accordingly, it is possible to reduce or prevent the likelihood of a situation in which a cutting error occurs due to the light emitting elements LE in the process of cutting the cutting cover area CUD of the second support film SPF2 according to the size of the display panels.

In addition, the mask frame MRF includes transmission openings OP respectively corresponding to the emission areas EA1, EA2, and EA3 of the display panel or the front surface areas of the display panel except for the cutting area. In addition, the mask frame MRF may further include a blocking portion MR corresponding to the non-emission area of the display panel.

The mask frame MRF is fixed by first and second frame binding units 521a and 521b positioned on any one side surface or a bottom surface of the transfer processing member 520, and thus is positioned on the front surface of the second support film SPF2 fixed by the film binding unit 522.

The film binding unit 522 is positioned on the rear surfaces of the first and second frame binding units 521a and 521b, and supports and fixes the second support film SPF2 by being piled on the rear surface of the second frame binding unit 521b. Accordingly, the film binding unit 522 locates the second support film SPF2 on the rear surface of the mask frame MRF. Accordingly, the light emitting elements LE arranged on the second support film SPF2 may pass through the transmission openings OP, and may be attached only to the display panel corresponding area of the second support film SPF2.

The frame fixing unit 523 is positioned on the rear surface of the film binding unit 522, and supports and fixes the pressing frame PWF by being overlapped with the rear surface of the film binding unit 522. Accordingly, the frame fixing unit 523 locates the pressing frame PWF on the rear surface of the second support film SPF2.

The pressing frame PWF includes a protruding pressing portion FP formed so that each of the areas corresponding to the emission areas EA1, EA2, and EA3 of the display panel and the transmission openings OP of the mask frame MRF protrudes, and also includes a support frame PF supporting the rear surface of the protruding pressing portion FP.

The protruding pressing portions FP may be formed to protrude from the support frame PF at a right angle or in a curved shape with a curvature. The protruding pressing portions FP may be formed of the aforementioned elastic member. The protruding pressing portions FP may increase the attachment success rate so that the light emitting elements LE are more strongly attached to the second support film SPF2 by pressing the rear surface of the second support film SPF2 corresponding to each of the front surface portion of the display panel, the emission areas EA1, EA2, and EA3 of the display panel, and the transmission openings OP of the mask frame MRF.

The plurality of light emitting elements LE whose arrangement width is varied on the second support film SPF2, due to the stretching of the second support film SPF2 by the stretching processing member 550 and due to the location movement of the front surface of the transfer processing member 520, are adhered to the second support film SPF2 of the transfer processing member 520.

The plurality of light emitting elements LE pass through the transmission openings OP of the mask frame MRF and are only adhered to areas EA1_D, EA2_D, and EA3_D corresponding to the transmission openings OP of the mask frame MRF in the entire area of the front surface of the second support film SPF2.

The transmission openings OP of the mask frame MRF may be formed to respectively correspond to the front surface areas of the display panel separated on a unit basis except for the cutting area because a plurality of cutting areas are cut. In addition, the transmission openings OP of the mask frame MRF may be formed to correspond to the emission areas EA1, EA2, and EA3 of the display panel. Accordingly, the light emitting elements LE passing through the transmission openings OP of the mask frame MRF and attached to the transmission corresponding areas EA1_D, EA2_D, and EA3_D of the second support film SPF2 may subsequently be attached to the front surface area of the display panel separated on a unit basis or the emission areas EA1, EA2, and EA3 of the display panel.

In the process of adhering the plurality of light emitting elements LE to only the areas EA1_D, EA2_D, and EA3_D corresponding to the transmission openings OP in the entire area of the front surface of the second support film SPF2, the rear surface of the second support film SPF2 corresponding to the transmission openings OP may be pressed with a stronger force by the protruding pressing portions FP of the pressing frame PWF. Accordingly, the plurality of light emitting elements LE may be adhered to the areas EA1_D, EA2_D, and EA3_D corresponding to the transmission openings OP in the entire area of the front surface of the second support film SPF2 with a stronger pressure.

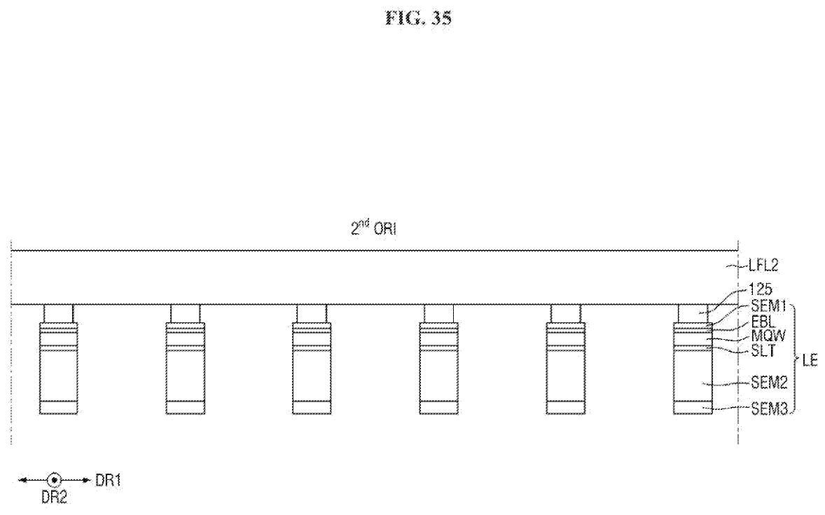

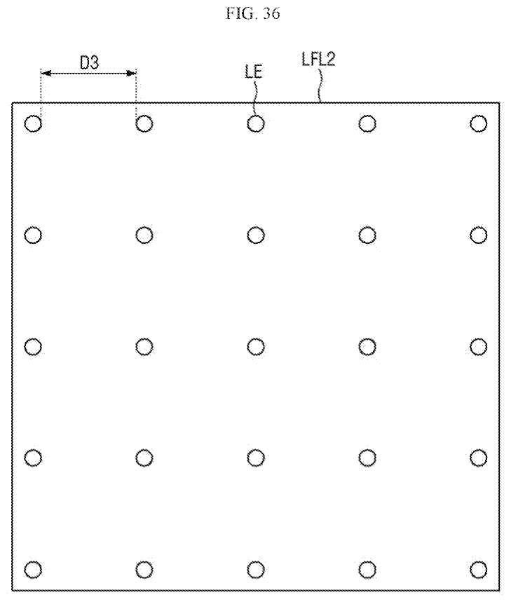

As illustrated in FIGS. 35 and 36, the second transfer film LFL2 is stretched (2^{nd} ORI) by the movement and pressure of the stretching processing member 550, so that the second transfer film LFL2 stretches two-dimensionally in the first direction DR1 and the second direction DR2. As the second transfer film LFL2 is stretched, the plurality of light emitting elements LE adhered to the second transfer film LFL2 may be spaced apart from each other by a third interval D3. That is, the plurality of light emitting elements LE may be substantially uniformly spaced apart from each other by a width of the third interval D3 that is greater than the second interval D2 described above (operation S140 of FIG. 15).

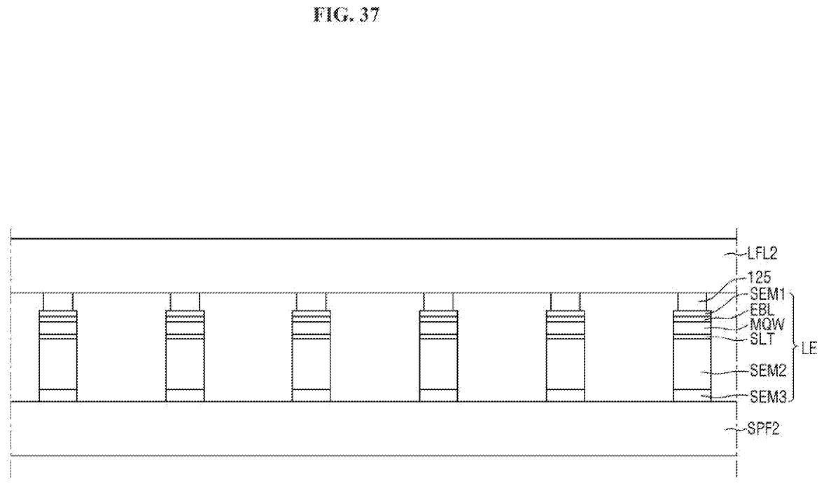

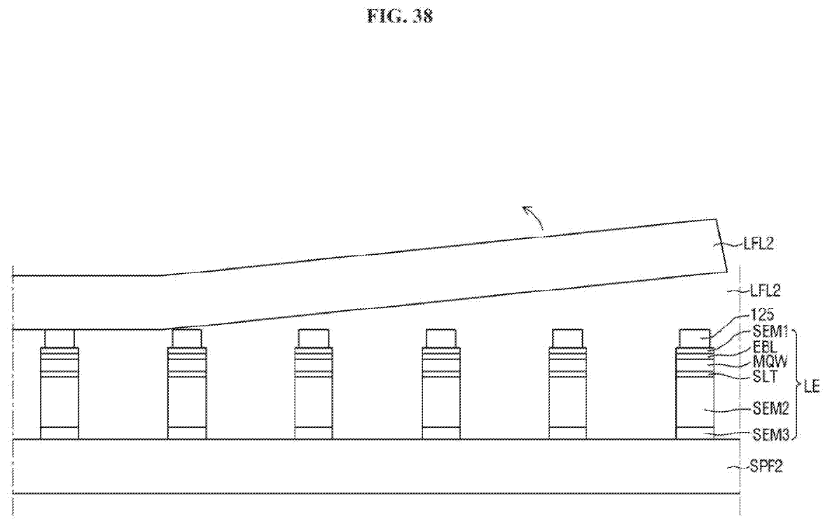

As in FIGS. 37 and 38, when the plurality of light emitting elements LE are adhered to the areas EA1_D, EA2_D, and EA3_D corresponding to the transmission openings OP in the entire area of the front surface of the second support film SPF2, the second transfer film LFL2 is separated from the plurality of light emitting elements LE. After UV or heat is applied to the second transfer film LFL2 to reduce the adhesive strength of the adhesive layer of the second transfer film LFL2, the second transfer film LFL2 may be physically or naturally separated.

Prior to the process of adhering the plurality of light emitting elements LE on the display substrate 100, at least one of the second transfer film LFL2 and the display substrate 100 may be cut to fit the size or area of the product and then be adhered.

When the at least one second transfer film LFL2 and the display substrate 100 are cut to fit the size or area of the product, the cut second support film SPF2, in which the plurality of light emitting elements LE are spaced apart from each other by the third interval D3, may be bonded to the display substrate 100 formed up to the pixel electrodes PE1, PE2, and PE3, so that the plurality of light emitting elements LE may be adhered to the display substrate 100 and a display panel may be fabricated.

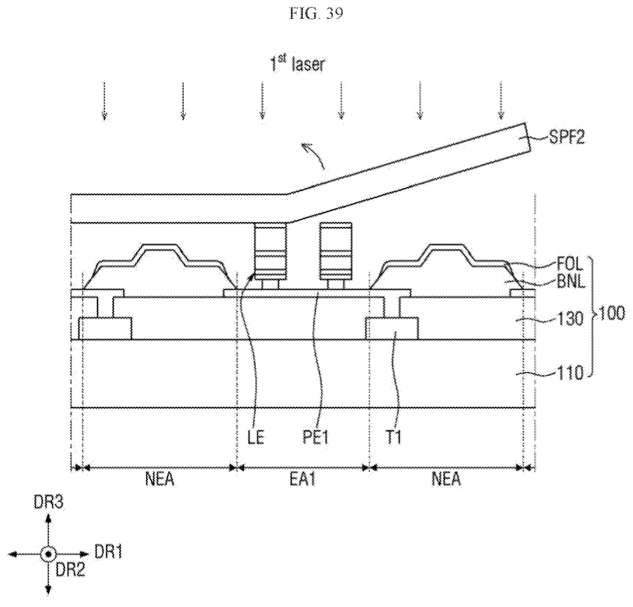

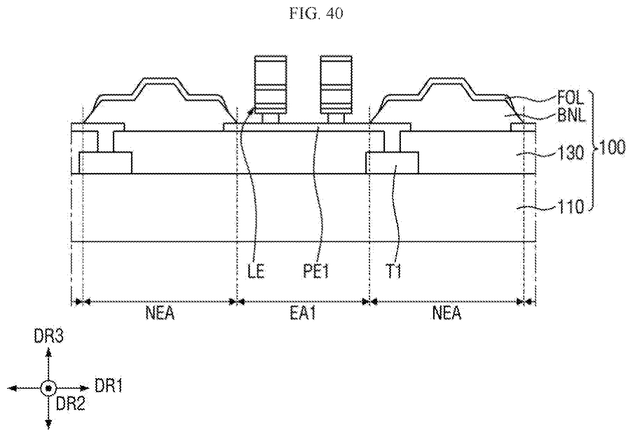

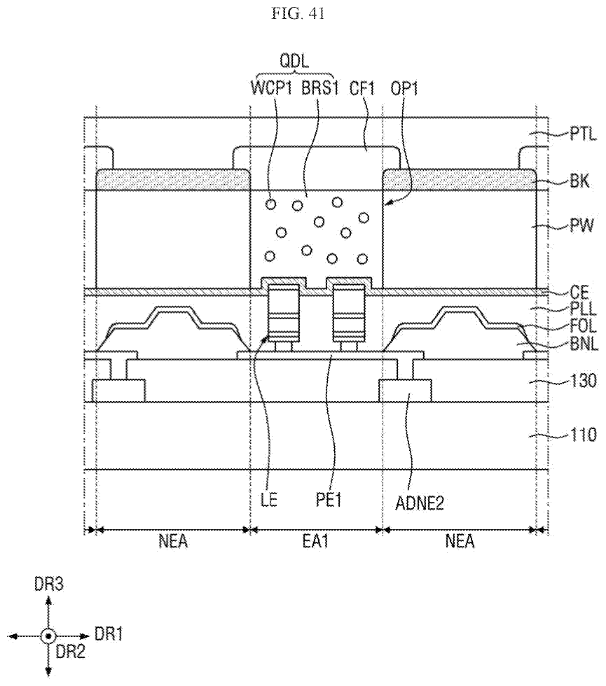

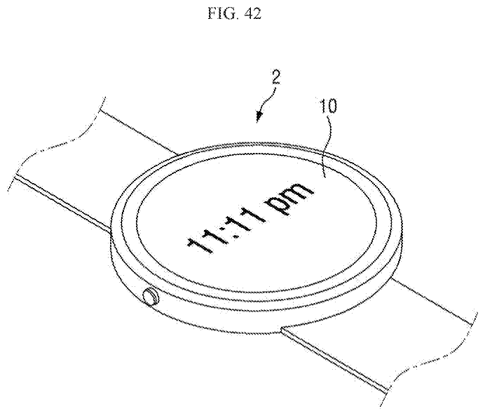

FIGS. 39 to 41 are cross-sectional views illustrating a method for fabricating a display panel according to one or more embodiments.

Referring to FIGS. 39 to 41, a display substrate including pixel circuits and the pixel electrodes PE1, PE2, and PE3 separately from the plurality of light emitting elements LE is fabricated (operation S150 of FIG. 15).

For example, when fabricating the display substrate, the first switching element T1 is formed on the first substrate 110, and the gate insulating layer 130 is formed on the first switching element T1. The first substrate 110 may be a transparent insulating substrate, or a glass or quartz substrate. The first switching element T1 may include a plurality of thin film transistors and capacitors. In the gate insulating layer 130, a contact hole exposing the first switching element T1 may be formed.

Next, a transparent conductive material is stacked on the gate insulating layer 130 and patterned to form a plurality of pixel electrodes, for example, the first pixel electrode PEI. The first pixel electrode PE1 may be connected to the first switching element T1 through a contact hole formed in the gate insulating layer 130. Then, a first organic material is applied on the first substrate 110 and patterned to form the bank BNL. The bank BNL exposes the first pixel electrode PE1 located therebelow to partition the first emission area EA1.

Next, a second organic material is applied on the first substrate 110 and patterned to form the first organic layer FOL. The first organic layer FOL may be formed on the bank BNL and may be spaced apart from the first emission area EA1. As described above, the first organic layer FOL may be a polyimide including a cyano group.

Next, the second support film SPF2 on which the plurality of light emitting elements LE are arranged is bonded to the display substrate 100 (operation S160 of FIG. 15).

For example, the connection electrode 125 of the light emitting element LE formed on the second support film SPF2 is brought into contact with the first pixel electrode PE1 of the display substrate 100. Next, the display substrate 100 and the second support film SPF2 are bonded to each other by fusion bonding the connection electrode 125 and the first pixel electrode PE1 at a temperature (e.g., a predetermined temperature). In this case, the plurality of light emitting elements LE are adhered to the top surface of the first pixel electrode PE1. For example, the connection electrode 125 and the first pixel electrode PE1 may have excellent adhesive properties because layers in contact with each other are made of the same material, for example, ITO.

Next, the second support film SPF2 is separated by a laser lift off (LLO) process, a planarization layer PLL is formed on the plurality of light emitting elements LE, the pixel electrode PE1, and the first organic layer FOL, and the common electrode CE is formed on the planarization layer PLL. The planarization layer PLL is formed to have a thickness such that the height of the planarization layer PLL is lower than the height of the light emitting element LE so that the second semiconductor layer SEM2 and the third semiconductor layer SEM3 of the light emitting element LE are exposed above the planarization layer PLL. Then, the common electrode CE is formed by depositing a transparent conductive material on the planarization layer PLL. The common electrode CE is formed to cover the plurality of light emitting elements LE and the planarization layer PLL. The common electrode CE is in contact with the second semiconductor layer SEM2 and the third semiconductor layer SEM3 of the light emitting element LE exposed on the planarization layer PLL.

Next, the partition wall PW including the plurality of openings OP1 is formed on the common electrode CE. The plurality of openings, for example, the first opening OP1, is formed to correspond to the first emission area EA1. In some embodiments, other openings are also formed to correspond to other emission areas.

Next, the wavelength conversion layer QDL is formed in the plurality of openings OP1. The wavelength conversion layer QDL may be formed to fill the plurality of openings OP1. The wavelength conversion layer QDL may be formed by a solution process such as inkjet printing or imprinting, but is not limited thereto. The wavelength conversion layer QDL may be formed in the plurality of openings OP1, and may be formed to overlap the plurality of emission areas EA1.

Next, the color filter CF1 and the light blocking member BK are formed on the wavelength conversion layer QDL. The light blocking member BK is formed by applying a light blocking material, and patterning the same. The light blocking member BK is formed to overlap the non-emission area NEA, and to not overlap the emission area EA1.

Next, the color filter CF1 is formed on the wavelength conversion layer QDL partitioned by the light blocking member BK. The color filter CF1 may be formed by a photo process. The color filter CF1 may have a thickness of about 1 μm or less, but is not limited thereto.

For example, a first color filter material layer is applied on the partition wall PW and the wavelength conversion layer QDL, and is patterned through a photo process to form the first color filter CF1 overlapping the first opening OP1. Similarly, other color filters are also formed to respectively overlap the openings through a patterning process. Next, a display panel according to one or more embodiments is fabricated by forming the passivation layer PTL on the light blocking member BK and the color filter CF1 (operation S170 of FIG. 15).

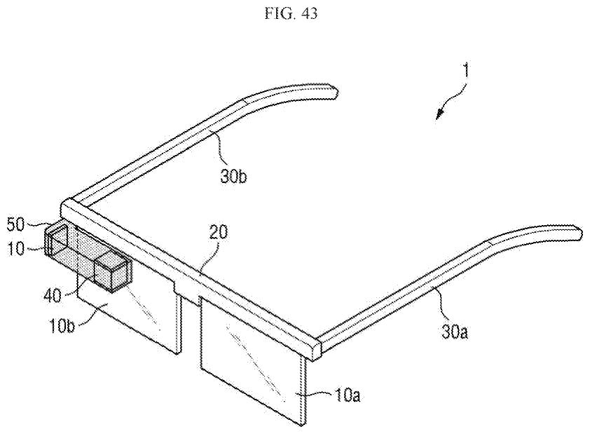

FIG. 42 is an diagram illustrating a smart device including a display panel according to one or more embodiments. FIG. 43 is an diagram illustrating a virtual reality device including a display panel according to one or more embodiments.

The display device 10 according to one or more embodiments may be applied to a smart watch 2 that is one of the smart devices. Further, a virtual reality device 1 according to one or more embodiments may be a glasses-type device. The virtual reality device 1 according to one or more embodiments may include the display device 10, a left lens 10a, a right lens 10b, a support frame 20, temples 30a and 30b, a reflection member 40, and a display device storage 50.

Although FIG. 43 illustrates the virtual reality device 1 including the temples 30a and 30b, the virtual reality device 1 according to one or more embodiments may be applied to a head mounted display including a head mounted band that may be worn on a head, instead of the temples 30a and 30b. That is, the virtual reality device 1 according to one or more embodiments is not limited to that shown in FIG. 43, and may be applied in various forms to various electronic devices.

The display device storage 50 may include the display device 10 and the reflection member 40. The image displayed on the display device 10 may be reflected by the reflection member 40 and provided to a user's right eye through the right lens 10b. Accordingly, the user can view the virtual reality image displayed on the display device 10 through the right eye.

FIG. 43 illustrates that the display device storage 50 is located at the end of the right side of a support frame 20, but the present specification is not limited thereto. For example, the display device storage 50 may be located at the left end of the support frame 20, and in this case, the image displayed on the display device 10 may be reflected by the reflection member 40 and provided to a user's left eye through the left lens 10a. Accordingly, the user can view the virtual reality image displayed on the display device 10 through the left eye. Alternatively, the display device storage 50 may be located at both the left end and the right end of the support frame 20. In that case, the user can view the virtual reality image displayed on the display device 10 through both the left eye and the right eye.

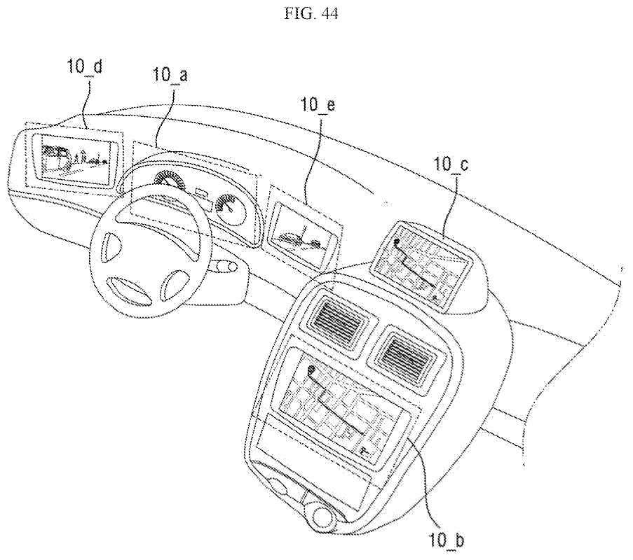

FIG. 44 is one diagram illustrating a vehicle including a display panel according to one or more embodiments.

Referring to FIG. 44, display devices 10_a, 10_b, and 10_c according to one or more embodiments may be applied to the dashboard of the automobile, the center fascia of the automobile, or the center information display (CID) of the dashboard of the automobile. Further, display devices 10_d, and 10_e according to one or more embodiments may be applied to a room mirror display instead of side mirrors of the automobile.

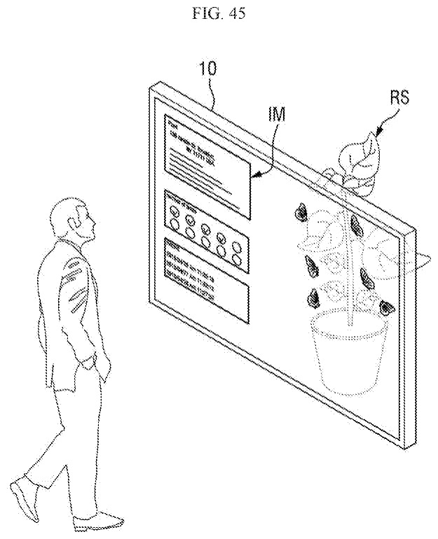

FIG. 45 is an diagram illustrating a transparent display device including a display panel according to one or more embodiments.

Referring to FIG. 45, the display device 10 according to one or more embodiments may be applied to the transparent display device. The transparent display device may display an image IM, and also may transmit light. Thus, a user located on the front side of the transparent display device can view an object RS or a background on the rear side of the transparent display device as well as the image IM displayed on the display device 10. When the display device 10 is applied to the transparent display device, the first substrate 110 of the display device 10 shown in FIG. 4 may include a light transmitting portion capable of transmitting light or may be made of a material capable of transmitting light.

In concluding the detailed description, those skilled in the art will appreciate that many variations and modifications can be made to the disclosed embodiments without substantially departing from the aspects of the present disclosure. Therefore, the disclosed embodiments are used in a generic and descriptive sense only, and not for purposes of limitation.

What is claimed is:

1. An apparatus for fabricating a display panel, the apparatus comprising:
a fixing frame configured to secure an outer periphery of a first transfer film on which light emitting elements are arranged;
a film mounting member on which the fixing frame is mounted;
a stretching processing member configured to stretch the first transfer film by pressing a rear surface of the first transfer film in a forward direction; and
a transfer processing member configured to transfer the light emitting elements to a support film or a second transfer film, the light emitting elements having an interval therebetween changed due to stretching of the first transfer film.

2. The apparatus of claim 1, wherein the fixing frame comprises first and second assembly frames having a circular or polygonal opening, and having a circular or polygonal panel or frame structure in which the opening is formed.

3. The apparatus of claim 2, wherein the first and second assembly frames are configured to overlap each other with the first transfer film therebetween, and are configured to press and secure partial areas of front and rear surfaces and an outer perimeter of the first transfer film due to a peripheral frame structure of the opening.

4. The apparatus of claim 1, wherein the film mounting member comprises:
a first mounting frame on which the fixing frame is seated; and
a second mounting frame configured to press and secure a portion of a front surface and an outer perimeter of the fixing frame seated on the first mounting frame.

5. The apparatus of claim 4, wherein the first mounting frame comprises a circular or polygonal panel or frame defining an opening, and is mounted on or inside a housing, and
wherein the second mounting frame comprises a circular or polygonal panel or frame defining an opening, and is configured to overlap the first mounting frame with the fixing frame therebetween.

6. The apparatus of claim 1, wherein the stretching processing member comprises:
a plate-shaped frame of a disk shape or polygonal shape;
an elastic press on a front surface of the plate-shaped frame; and
a transfer driving member configured to stretch the first transfer film with the elastic press and the plate-shaped frame by supporting a rear surface of the plate-shaped frame, and by moving the plate-shaped frame in a forward direction from the rear surface of the first transfer film toward a front surface of the first transfer film.

7. The apparatus of claim 6, wherein the elastic press comprises a convex shape of a front surface having curvature, and a substantially flat rear surface on the front surface of the plate-shaped frame.

8. The apparatus of claim 7, wherein the convex shape of the elastic press corresponds to at least one of a size or diameter of the first transfer film, an arrangement width or arrangement interval of the light emitting elements, or a stretching width of the first transfer film.

9. The apparatus of claim 1, wherein the transfer processing member is configured to move in a direction of the first transfer film stretched by the stretching processing member in a state in which the support film or the second transfer film is mounted, and is configured to adhere the light emitting elements to the support film or to the second transfer film, and
wherein the light emitting elements are configured to transfer to the support film or to the second transfer film in a process of detachment away from the first transfer film.

10. The apparatus of claim 1, wherein the transfer processing member comprises:
first and second frame binding units configured to secure an outer perimeter of a mask frame by pressing the outer perimeter of the mask frame;
a film binding unit assembled to a rear surface of the second frame binding unit to secure the support film or the second transfer film to a rear surface of the mask frame; and
a frame fixing unit assembled to a rear surface of the film binding unit to secure a pressing frame to a rear surface of the support film or the second transfer film.

11. The apparatus of claim 10, wherein the first and second frame binding units comprise a circular or polygonal panel or frame structure having an opening, overlap each other with the mask frame therebetween, and are configured to press and secure partial areas of front and rear surfaces and an outer perimeter of the mask frame.

12. The apparatus of claim 11, wherein the mask frame comprises:
a cutting line portion corresponding to a cutting cover area of a second support film corresponding to a cutting area of the display panel for covering the light emitting elements such that they are not attached to the cutting cover area of the second support film;
transmission openings respectively corresponding to emission areas of the display panel or front surface areas of the display panel excluding a cutting area; and
a blocking portion corresponding to a non-emission area of the display panel.

13. The apparatus of claim 12, wherein the frame fixing unit comprises a circular or polygonal panel or frame structure having an opening, overlaps the rear surface of the film binding unit with the pressing frame therebetween, and is configured to press and secure partial areas of front and rear surfaces and an outer perimeter of the pressing frame.

14. The apparatus of claim 13, wherein the pressing frame comprises:
protruding pressing portions formed such that areas corresponding to transmission openings of the mask frame and emission areas of the display panel protrude in a right-angled or curved shape; and
a support frame configured to support rear surfaces of the protruding pressing portions.

15. A fabricating method of a display panel, the method comprising:
fabricating a display substrate comprising pixel circuits and pixel electrodes;
fabricating light emitting elements on a base substrate;
moving and transferring the light emitting elements to a first transfer film;
fixing an outer perimeter of the first transfer film with a fixing frame;
mounting the fixing frame to a film mounting member;
primarily stretching a width of the first transfer film by pressing a rear surface of the first transfer film with a stretching processing member; and
transferring the light emitting elements having an interval changed due to the stretching to a support film or a second transfer film mounted on a transfer processing member.

16. The fabricating method of claim 15, further comprising:
fixing an outer perimeter of the second transfer film, to which the light emitting elements are transferred, with the fixing frame;
mounting the fixing frame on the film mounting member;
secondarily stretching the second transfer film by pressing a rear surface of the second transfer film with the stretching processing member;
transferring the light emitting elements having another interval changed due to the secondarily stretching the second transfer film to the support film mounted on the transfer processing member; and
locating the light emitting elements transferred to the support film on the pixel electrodes of the display substrate.

17. The fabricating method of claim 16, wherein the transferring of the light emitting elements to the support film or to the second transfer film mounted on the transfer processing member comprises:
fixing a mask frame to first and second frame binding units of the transfer processing member;
fixing the support film or the second transfer film with a film binding unit assembled to a rear surface of the second frame binding unit;
fixing a pressing frame with a frame fixing unit assembled to a rear surface of the film binding unit; and
moving the transfer processing member comprising the first and second frame binding units, the film binding unit, and the frame fixing unit to bring the support film or the second transfer film into contact with the light emitting elements.

18. The fabricating method of claim 17, wherein the fixing of the mask frame to the first and second frame binding units comprises:
locating the mask frame between the first and second frame binding units comprising a circular or polygonal panel or frame structure having an opening; and
fixing partial areas of front and rear surfaces and an outer perimeter of the mask frame by overlapping the first and second frame binding units with the mask frame therebetween.

19. The fabricating method of claim 18, wherein the fixing of the support film or the second transfer film with the film binding unit comprises:
locating the support film or the second transfer film between the second frame binding unit and the pressing frame; and
fixing the support film or the second transfer film by overlapping the film binding unit with the rear surface of the second frame binding unit with the support film or the second transfer film therebetween.

20. The fabricating method of claim 19, wherein the fixing of the pressing frame with the frame fixing unit assembled to the rear surface of the film binding unit comprises:
locating the pressing frame between the film binding unit and the frame fixing unit; and
fixing the support film or the second transfer film by overlapping the frame fixing unit with the rear surface of the film binding unit with the pressing frame therebetween.
